(19) United States
(12) Patent Application Publication
(10) Pub. No.: US 2018/0246382 A1
(43) Pub. Date: Aug. 30, 2018

(54) DISPLAY PANEL AND METHOD OF PRODUCING DISPLAY PANEL

(71) Applicant: SHARP KABUSHIKI KAISHA, Sakai City, Osaka (JP)

(72) Inventors: YUDAI TAKANISHI, Sakai City (JP); RYUJI MATSUMOTO, Sakai City (JP); YOSHIMASA CHIKAMA, Sakai City (JP)

(21) Appl. No.: 15/755,550

(22) PCT Filed: Aug. 26, 2016
(86) PCT No.: PCT/JP2016/074988

§ 371 Date: Feb. 27, 2018

(30) Foreign Application Priority Data
Aug. 31, 2015 (JP) 2015-170363

(51) Int. Cl. G02F 1/1337; G02F 1/1339; G02F 1/1333; G03F 7/00

(52) U.S. Cl. CPC G02F 1/133788; G02F 1/1339; G02F 1/1368; G03F 7/0007; G02F 1/133345

(57) ABSTRACT

A liquid crystal panel includes boards, a sealing member, an insulating film, an alignment film, and a film forming area control recess. The sealing member is disposed between the boards. The insulating film is formed on an array board. The alignment film is formed to overlap the insulating film on the array board at least in the display area. The film forming area control recess is formed by recessing a section of the insulating film at a position closer to the display area AA relative to the sealing member on the array board. The film forming area control recess is configured such that at least a section of a first side surface on a sealing member side is angled relative to a normal direction to a plate surface of the array board with a smaller angle in comparison to a second side surface on an opposite side.

### TECHNICAL FIELD

The present invention relates to a display panel and a method of producing a display panel.

### BACKGROUND ART

A liquid crystal panel disclosed in Patent Document 1 has been known as an example of a liquid crystal panel that is a major component of a liquid crystal display device. In this liquid crystal panel, alignment films are formed on surfaces of a first substrate and a second substrate on liquid crystal layer sides by curing materials of the alignment films having flowability. The alignment films are formed to cover a display area and a frame area. At least one of the first substrate and the second substrate includes a supporting board and a supporting structure that are formed on the supporting boards. At least a surface of the supporting structure on an opposite side from the supporting board is directly covered with the alignment film. The supporting structure includes a side portion. The side portion includes a flat contact surface that is angled toward an outside of the supporting structure to a supporting board side. The side portion of the supporting structure is disposed in the frame area to support edges of the alignment film. An insulating film includes a recess along a sealing member. A section of an inner wall surface of the recess is the side portion of the supporting structure.

### RELATED ART DOCUMENT

### Patent Document

Patent Document 1: International Patent Application Publication No. 2011/086624

### Problem to be Solved by the Invention

In Patent Document 1,

In Patent Document 1, the contact flat surface of the side portion of the supporting structure is angled toward the outside of the supporting structure to the supporting board side. The edges of the alignment film are supported with a viscous property of the flat contact surface. Therefore, the spread of the material of the alignment film is reduced. In practice, conditions including a supply of the material of the alignment film and the viscous of the material of the alignment film may vary. In some cases, the supporting structure may not be able to support the material of the alignment film. If the supporting structure cannot support the material of the alignment film, the material of the alignment film may accumulate in the recessed portion. In recent years, a reduction in frame size is in progress. According to the reduction in frame size, an area to form the recess becomes smaller. Therefore, the alignment film material may flow over from the recess and reach a position to overlap the sealing member.

### DISCLOSURE OF THE PRESENT INVENTION

The present invention was made in view of the above circumstances. An object is to properly control a forming area to form an alignment film.

### Means for Solving the Problem

A display panel according to the present invention includes a pair of boards, a sealing member, an insulating film, as alignment film, and a film forming area control recess. The boards include sections in a display area and sections in a non-display area outside the display area. The boards are opposed to each other with an internal space therebetween. The sealing member is disposed in the non-display area between the boards to surround the internal space and to seal the internal space. The insulating film is formed on a first board of the boards. The alignment film is disposed in at least the section of the first board in the display area to overlap the insulating film. The film forming area control recess is formed by recessing a section of the insulating film at a position closer to the display area relative to the sealing member on the first board to control a forming area to form the alignment film. The film forming area control recess includes a first side surface on a sealing member side and a second side surface on an opposite side from the sealing member side. At least a section of the first side surface is angled relative to a normal direction to a plate surface of the first board with a smaller angle in comparison to the second side surface.

As described above, the alignment film is disposed at least in the display area. To form the alignment film, a material of the alignment film having a flowability is supplied to the section of the first board in the display area. The material flows and spreads over a surface of the insulating film on the first board. As a result, the alignment film is formed to overlap the surface of the insulating film. If the material of the alignment film supplied to the display area flows toward the sealing member in the non-display area, the material flows into the film forming area control recess that is formed by recessing the section of the insulating film at the position closer to the display area relative to the sealing member on the first board. The second side surface of the film forming area control recess on the opposite side from the sealing member side is angled relative to the normal direction to the plate surface of the first board with a larger angle in comparison to the first side surface. Therefore, the second side surface can properly direct the material of the alignment film having the flowability into the film forming area control recess. The first side surface of the film forming area control recess on the sealing side is angled relative to the normal direction to the plate surface of the first board with the smaller angle in comparison to the second side surface. Therefore, the material of the alignment film directed into the film forming area control recess is less likely to flow over the film forming area control recess and reach the position to overlap the sealing member. According to the configuration, the alignment film is less likely to be disposed to overlap the sealing member and thus fixing strength of the sealing member relative to the first board is maintained at a high level. Even if a width of the film forming area control recess is reduced due to a reduction in frame size, reach of the material of the alignment film to the position to overlap the sealing member can be properly restricted during the formation of the alignment film.

Preferable embodiments of the display panel according to the present invention may include the following configurations.

(1) The film forming area control recess may be disposed in the non-display area. According to the configuration, the film forming area control recess is less likely to exert an adverse effect on display quality of images that are displaced in the display area.

(2) The first side surface of the film forming area control recess may include at least a steep slope and a gentle slopes. The slope may be angled relative to the normal direction to the plate surface of the first board with a smaller angle in comparison to the second side surface. The gentle slope may be disposed closer to the display area in comparison to the steep slope and angled relative to the normal direction to the plate surface of the first board with a larger angle in comparison to the steep slope. According to the configuration, when the material of the alignment film is directed into the film forming area control recess through the second side surface during the formation of the alignment film, the material may flow over the gentle slope that is disposed closer to the display area relative to the steep slope of the first side surface and angled relative to the normal direction to the plate surface of the first board with the larger angle in comparison to the steep slope. However, the film forming area is limited by the steep slope that is angle relative to the normal direction to the plate surface of the first board with the smaller angle in comparison to the second side surface. Because the material of the alignment film can easily flow over the gentle slope, in comparison to a configuration in which the film forming area control recess includes the steep slope for the entire area, a larger amount of the material of the alignment film is retained in the film forming area control recess.

(3) The display panel may include a second film forming area control recess that is formed by recessing a section of the insulating film on an opposite side from the sealing member side relative to the film forming area control recess. The second film forming area control recess may be shallower than the film forming area control recess. The second film forming area control recess may include a bottom surface that is at a height aligned with a height at which a boundary between the gentle slope and the steep slope of the film forming area control recess. According to the configuration, the material of the alignment film having the flowability flows into the second film forming area control recess before reaching the film forming area control recess. Therefore, the reach of the material of the alignment film to the position to overlap the sealing member is further properly restricted. Furthermore, according to the configuration described above, when the insulating film is partially etched to form the film forming area control recess and the second film forming area control recess, the film forming area control recess and the second film forcing area control recess can be simultaneously formed in the same etching process. Therefore, a production cost and takt time can be reduced.

(4) The display panel may include a second film forming area control recess that may be formed by recessing a section of the insulating film on an opposite side from the sealing member side relative to the film forming area control recess. According to the configuration, the material of the alignment film having the flowability flows into the second film forming area control recess before reaching the film forming area control recess. Therefore, the reach of the material of the alignment film to the position to overlap the sealing member is further properly restricted.

(5) The second film forming area control recess may be shallower than the film forming area control recess. Because the second film forming area control recess that is disposed on the opposite side from the sealing member side may be shallower than the film forming area control recess, this configuration is preferable for ensuring insulating performance of the insulating film.

(6) The second board of the boards may include a board support that protrudes toward the first board to support the first board. The board support may be disposed not to overlap the film forming area control recess and the second film forming area control recess. According to the configuration, the board support of the second board may not overlap the film forming area control recess and the second film forming area control recess. Therefore, the first board is further properly supported by the board support and thus the height of the internal space can be properly maintained.

(7) The insulating film may include a step at a position to overlap the sealing member. According to the configuration, in comparison to a configuration in which a section of the insulating film overlapping the sealing member is flat, a contact area between the insulating film and the sealing member increases. Therefore, the fixing strength of the sealing member relative to the insulating film increases. Furthermore, through the processing that is performed on the insulating film to form the step, the step has surface roughness. Therefore, the fixing strength of the sealing member relative to the insulating film further increases.

(8) The display panel may further include a trace that is disposed to overlap the insulating film on an opposite side from an alignment film side on the first board in the non-display area. In a configuration in which a trace is disposed to overlap the insulating film on an opposite side from the alignment film side on the first board in the non-display area, it tends to be difficult to maintain the film forming area control recess with a sufficiently large width to ensure the insulating performance of the insulating film for the trace. Because at least the section of the first side surface of the film forming area control recess is angled relative to the normal direction to the plate surface of the first board in comparison to the second side surface, even if the film forming area control recess cannot be provided with the sufficiently large width, the forcing area to form the alignment film can be properly limited.

(9) The film forming area control recess may be disposed to overlap the trace. This configuration is preferable for reducing the frame size.

(10) The film forming area control recess may be disposed to overlap the trace and the sealing member. This configuration is preferable for reducing the frame size.

A method of producing a display panel according to the present invention includes at least an insulating film forming process, a film forming area control recess forming process, an alignment film forming process, and a sealing member forming process. In the insulating film forming process, an insulating film is formed on a first board of a pair of boards including sections in a display area and sections in a non-display area outside the display area. The boards are opposed to each other with an internal space therebetween. The internal space is sealed with a sealing member that is disposed in the non-display area to surround the internal space. In the film forming area control recess forming process, the film forming area control recess is formed by recessing at least a section of the insulating film on the first board at a position closer to the display area relative to a position to form the sealing member such that at least a section of a first side surface of the film forcing area control recess on a sealing member side is angled relative to a normal direction to a plate surface of the first board with a smaller angle in comparison a second side surface of the film forming area control recess on an opposite side from the sealing member side. The film forming area control recess is for controlling a forming area to form an alignment film. In the alignment film forming process, the alignment film is formed to overlap the insulating film on the first board. In the sealing member forming process, the sealing member may be formed between the boards.

In the insulating film forming process, the insulating film is formed on the first board of the boards. In the film forming area control recess forming process, the film forming area control recess for controlling the forming area to form the alignment film is formed by recessing at least the section of the insulating film on the first board at the position closer to the display area relative to the position to form the sealing member. In the alignment film forming process, the alignment film is formed to overlap the insulating film on the first board. In the sealing member forming process, the sealing member is formed between the boards.

In the alignment film forming process, the material of the alignment film having the flowability is supplied to the section of the first board in the display area. The material flows and spreads over the surface of the insulating film formed on the first board. As a result, the alignment film is formed to overlap the surface of the insulating film. If the material of the alignment film supplied to the display area flows toward the position to form the sealing member in the non-display area, the material of the alignment film flows into the film forming area control recess that is formed by recessing the section of the insulating film on the first board at the position closer to the display area relative to the sealing member. In the film forming area control recess forming process, the film forming area control recess is formed such that the second side surface on the opposite side from the sealing member side is angled relative to the normal direction to the plate surface of the first board with the larger angle in comparison to the first side surface. Therefore, the material of the alignment film having the flowability is properly directed into the film forming area control recess. In the film forming area control recess forming process, the first side surface of the film forming area control recess on the sealing member side is angled relative to the normal direction to the plate surface of the first board with the smaller angle in comparison to the second side surface. Therefore, the material of the alignment film directed into the film forming area control recess is less likely to flow over the film forming area control recess and reach the position to overlap the sealing member. According to the configuration, the alignment film is leas likely to be disposed to overlap the sealing member and thus the fixing strength of the sealing member is maintained at the high level. Even if the width of the film forming area control recess is reduced due to the reduction in frame size, the reach of the material of the alignment film to the position to overlap the sealing member can be properly restricted during the formation of the alignment film in the alignment film forming process.

Preferable embodiments of the method of producing the display panel according to the present invention may include the following features.

(1) The film forming area control recess forming process may include at least an interim film forming area control recess forming process, a resist forming process, an etching process, and a resist removal process. In the interim film forming area control recess forming process, an interim film forming area control recess may be temporarily formed in the sealing member at least at a position closer to the display area relative to a position to form the sealing member. The interim film forming area control recess may include an interim first side surface and the second side surface that are angled relative to a normal direction to a plate surface of the first board with angles that are equal to each other. In the resist forming process, a resist that may include a hole at least at a position to overlap the interim first side surface of the interim film forming area control recess of the insulating film. In the etching process, the insulating film may be etched via the resist. In the resist removal process, the resist may be removed from the insulating film. In the interim film forming area control recess forming process included in the film forming area control recess forming process, the interim film forming area control recess may be temporarily formed in the insulating film at least at the position closer to the display area relative to the position to form the sealing member. The interim film forming area control recess may include the interim first side surface and the second side surface that may be angled relative to the normal direction to the plate surface of the first board with the angles that are equal to each other. In the resist forming process that may be performed next, the resist may be formed to overlap the insulating film. The resist may include the hole at least at the position to overlap the interim first side surface of the interim film forming area control recess of the insulating film. When the etching process is performed afterward, a section of the insulating film overlapping the hole of the resist may be selectively etched. As a result, the film forming area control recess that may include the first side surface that may be angled relative to the normal direction to the plate surface of the first board with the smaller angle in comparison to the second side surface may be formed. Then, through the resist removal process, the resist may be removed.

(2) In the etching process, dry etching may be performed. According to the method, the insulating film can be processed with higher accuracy in comparison to wet etching.

(3) In the insulating film forming process, the insulating film may be formed using a photosensitive material. The film forming area control recess forming process may include at least an exposing process and a developing process. In the exposing process, the insulating film may be exposed using a halftone mask or a grey tone mask as a photomask. The halftone mask may include a transmissible area and a semitransmissive area. The grey tone mask may include a transmissive area and a semitransmissive area. The halftone mask or the grey tone mask may be disposed such that at least the semitransmissive area may be at a position to overlap a position to form the second side surface. In the developing process, the insulating film may be developed. In the insulating film forming process, the insulating film may be formed using the photosensitive material. In the developing process included in the film forming area control recess forming process, the insulating film may be exposed using the halftone mask that may include the transmissive area and the semitransmissive area or the grey tone mask that may include the transmissive area and the semitransmissive area. In the developing process, the insulating film is developed. Through the processes, the film forming area control recess is formed. At least the semitransmissive area of the halftone mask or the grey tone mask used in the exposing process may be disposed at the position to overlap the position to form the second side surface of the film forming area control recess. Therefore, the second side surface of the film forming area control recess of the exposed and developed insulating film may be angled relative to the normal direction to the plate surface of the first board in comparison to the first side surface. If the photosensitive material is a positive type, the transmissive area of the halftone mask or the grey tone mask may be disposed at a position to overlap at least the position to form the first side surface of the film forming area control recess of the insulating film. If the photosensitive material is a negative type, the transmissive area of the halftone mask or the grey tone mask may be disposed at a position not to overlap at least the positions to form the first side surface and the second side surface of the film forming area control recess of the insulating film. According to the arrangement, the first side surface of the film forming area control recess of the exposed and developed insulating film may be angled relative to the normal direction of the plate surface of the first board with the smaller angle in comparison to the second side surface. Through the single exposing process, the film forming area control recess that may include the first side surface and the second side surface that may be angled relative to the normal direction to the plate surface of the first board with the angles that are different from each other. Therefore, time that is required for the production can be reduced.

### Advantageous Effect of the Invention

According to the present invention, the forming area to form the alignment film can be properly controlled.

### BRIEF DESCRIPTION OF THE DRAWINGS

FIG. 1 is a schematic plan view illustrating connection among a liquid crystal panel that includes a drive according to a first embodiment of the present invention, a flexible circuit board, and a control circuit board.

FIG. 2 is a schematic cross-sectional view illustrating a cross-sectional configuration along a short direction of a liquid crystal display device.

FIG. 3 is a schematic cross-sectional view illustrating as overall cross-sectional configuration of the liquid crystal panel.

FIG. 4 is a schematic cross-sectional view illustrating a cross sectional configuration of a section of the liquid crystal panel in a display area.

FIG. 5 is a plan view schematically illustrating a wiring configuration of an array board included in the liquid crystal panel.

FIG. 6 is a plan view illustrating a wiring configuration of TFTs in a peripheral section of the liquid crystal panel and positional relations among control circuits, a sealing member, a film forming area control recess, and the display area.

FIG. 7 is a cross-sectional view illustrating a cross-sectional configuration of the peripheral section of the liquid crystal panel.

FIG. 8 is a cross-sectional view illustrating an exposing process of exposing an insulating film using a photomask in an interim film forming area control recess forming process included in a film forming area control recess forming process.

FIG. 9 is a cross-sectional view illustrating a developing process of developing the insulating film exposed in the interim film forming area control recess forming process included in a film forming area control recess forming process.

FIG. 10 is a cross-sectional view illustrating an etching process of etching the insulating film via a resist in the film forming area control recess forming process.

FIG. 11 is a cross-sectional view illustrating a resist removal process of removing the resist in the film forming area control recess forming process.

FIG. 12 is a cross-sectional view illustrating an alignment film forming process of applying liquid droplets of a material of an alignment film onto the array board.

FIG. 13 is a cross-sectional view illustrating a cross-sectional configuration of a peripheral section of a liquid crystal panel according to a second embodiment of the present invention.

FIG. 14 is a cross-sectional view illustrating an etching process of etching an insulating film via a resist in a film forming area control recess forming process.

FIG. 15 is a cross-sectional view illustrating a resist removal process of removing the resist in the film forming area control recess forming process.

FIG. 16 is a cross-sectional view illustrating a cross-sectional configuration of a peripheral section of a liquid crystal panel according to a third embodiment of the present invention.

FIG.. 17 is a cross-sectional view illustrating an etching process of etching an insulating film via a resist in a film forming area control recess forming process.

FIG. 18 is a cross-sectional view illustrating a resist removal process of removing the resist in the film forming area control recess forming process.

FIG. 19 is a cross-sectional view illustrating a cross-sectional configuration of a peripheral section of a liquid crystal panel according to a fourth embodiment of the present invention.

FIG. 20 is a cross-sectional view illustrating an etching process of etching an insulating film via a resist in a film forming area control recess forming process.

FIG. 21 is a cross-sectional view illustrating a resist removal process of removing the resist in the film forming area control recess forming process.

FIG. 22 is a cross-sectional view illustrating a cross-sectional configuration of a peripheral section of a liquid crystal panel according to a fifth embodiment of the present invention.

FIG. 23 is a cross-sectional view illustrating an exposing process of exposing an insulating film via a grey tone mask in a film forming area control recess forming process according to a sixth embodiment of the present invention.

FIG. 24 is a cross-sectional view illustrating a developing process of developing the insulating film in the film forming area control recess forming process.

FIG. 25 is a cross-sectional view illustrating an exposing process of exposing an insulating film via a halftone mask in a film forming area control recess forming process according to a seventh embodiment of the present invention.

FIG. 26 is a plan view illustrating positional relations among control circuits, a sealing member, a film forming area control recess, and a display area according to an eighth embodiment of the present invention.

FIG. 27 is a cross-sectional view illustrating a cross-sectional configuration of a peripheral section of a liquid crystal panel

FIG. 28 is a plan view illustrating positional relations among control circuits, a sealing member, a film forming area control recess, and a display area according to an eighth embodiment of the present invention.

FIG. 29 is a cross-sectional view illustrating a cross-sectional configuration of a peripheral section of a liquid crystal panel.

### MODE FOR CARRYING OUT THE INVENTION

### First Embodiment

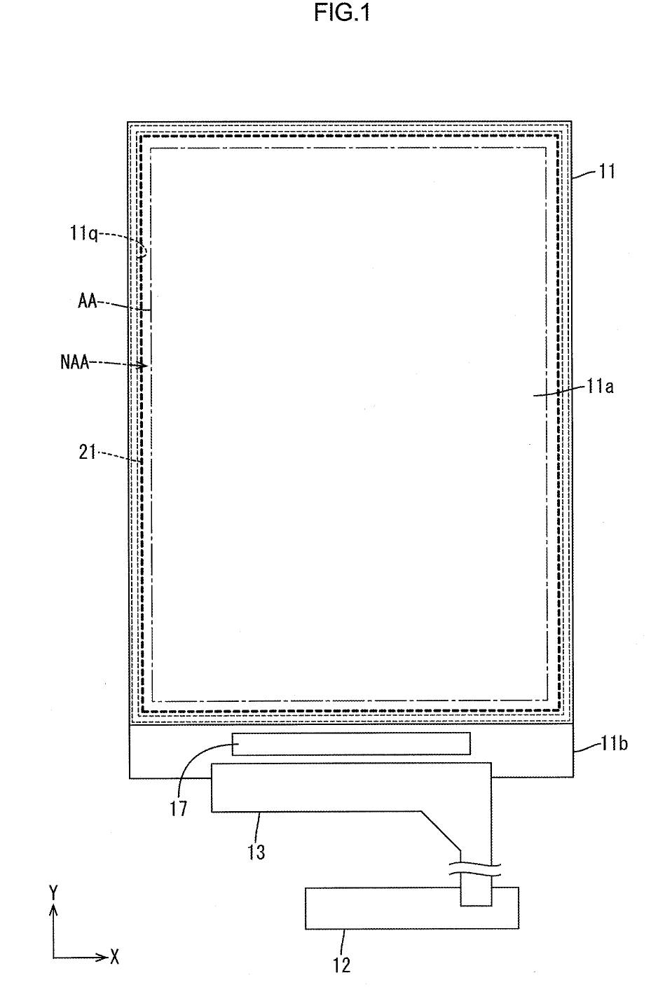

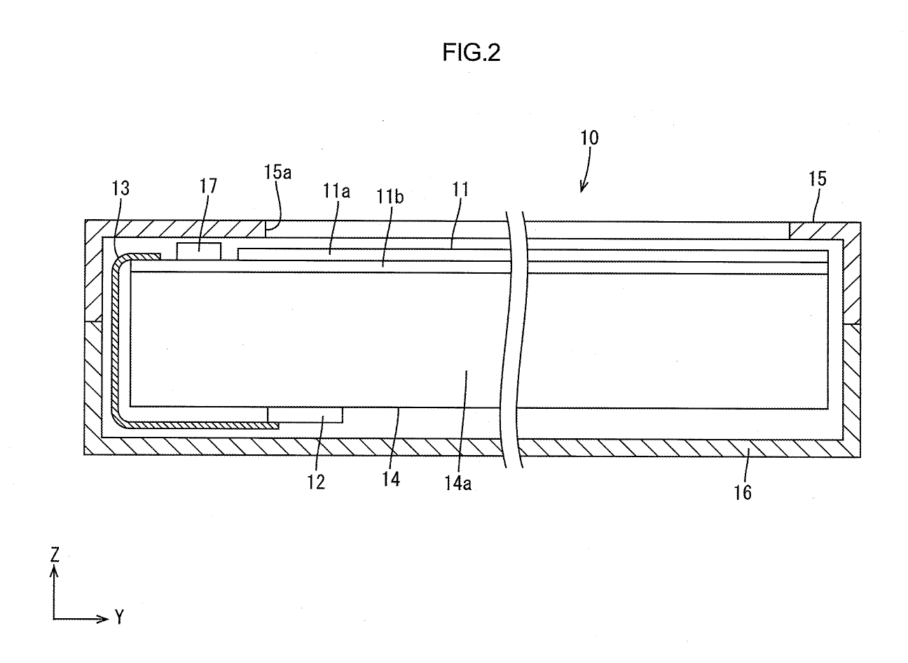

A first embodiment of the present invention will be described with reference to FIGS. 1 to 12. In this section, a liquid crystal display device 10 will be described. X-axes, Y-axes, and Z-axes may be present in drawings. The axes in each drawing correspond to the respective axes in other drawings to indicate the respective directions. A vertical direction of the liquid crystal display device 10 is defined based on FIGS. 2 to 4. Upper sides and lower sides in in FIGS. 2 to 4 correspond to a front side and a rear side of the liquid crystal display device 10, respectively.

As illustrated in FIGS. 1 and 2, the liquid crystal display device 10 includes a liquid crystal panel 11 (a display panel), a driver 17 (a panel driver), a control circuit board 12 (an external signal source), a flexible circuit board 13 (an external connecting component), and a backlight unit 14 (a lighting device). The liquid crystal panel 11 is configured to display images. The liquid crystal panel 11 includes a display area AA and a non-display area NAA. The display area AA is an inner area configured to display images. The non-display area NAA is an outer area to surround the display area AA. The driver 17 is configured to drive the liquid crystal panel 11. The control circuit board 12 is configured to supply various kinds of signals from outside to the driver 17. The flexible circuit board 13 electrically connects the liquid crystal panel 11 to the control circuit board 12 that is provided outside. The backlight unit 14 is an external light source for supplying light to the liquid crystal panel 11. The liquid crystal display device 10 includes a front exterior component 15 and a rear exterior component 16 provided as a pair to hold the liquid crystal panel 11 and the backlight unit 14 that are assemble together. The front exterior component 15 includes an opening 15a through which images displayed in the display area AA of the liquid crystal panel 11 can viewed from the outside. The liquid crystal display device 10 according to this embodiment may be used in, but not limited to, an electronic device (not illustrated). Examples of the electronic device include mobile phones (including smart phones), laptop computers (including tablet-type laptop computers), wearable terminals (including smartwatches), mobile information terminals (including electronic books and PDAs), portable video game players, and digital photo frames. Therefore, a screen size of the liquid crystal panel 11 included in the liquid crystal display device 10 may be from several inches to a ten and several inches, which is usually classified as a small or a small-to-medium screen size.

The backlight unit 14 will be briefly described. As illustrated in FIG. 2, the backlight unit 14 includes a chassis 14a, a light source (e.g. cold cathode fluorescent tubes, LEDs, organic ELs), which are not illustrated, and an optical member, which is not illustrated. The chassis 14a has a box-like shape. The light sources are disposed inside the chassis 14a. The optical member is disposed to cover an opening of the chassis 14a. The optical member is configured to convert light emitted by the light sources into planar light.

Next, the liquid crystal panel 11 will be described. As illustrated in FIG. 1, the liquid crystal panel 11 has a vertically-long rectangular overall shape. At a position closer to a first end of the liquid crystal pane 11 with respect to a long direction of the liquid crystal panel 11 (the upper side in FIG. 1), the display area AA (an active area) is provided. The driver 17 and the flexible circuit board 13 are mounted at positions closer to a second end of the liquid crystal panel 11 with respect to the long direction of the liquid crystal panel 11 (the lower side in FIG. 1). In the liquid crystal panel 11, the area outside the display area AA is the non-display area NAA (a non-active area) in which images are not displayed. The non-display area NAA includes a frame-shaped region that surrounds the display area AA (a frame-shaped section of a CF board 11a, which will be described later) and a region that is provided at the second end with respect to the long direction (a section of an array board 11b which is exposed without overlapping the CF board 11a, which will be described later). The region provided at the second end with respect to the long direction includes a mounting region (an attachment region) in which the driver 17 and the flexible circuit board 13 are mounted. The short direction of the liquid crystal panel 11 corresponds with the X-axis direction in the drawings and the long direction of the liquid crystal panel 11 corresponds with the Y-axis direction in the drawings. In FIGS. 1, 5, and 6, a chain line slightly smaller than the CF board 11a in a frame shape indicates an outline of the display area AA and an area outside the chain line is the non-display area NAA.

Next, the components connected to the liquid crystal panel 11 will be described. As illustrated in FIGS. 1 and 2, the control circuit board 12 is mounted to a back surface of the chassis 14a of the backlight unit 14 (an outer surface on an opposite side from the liquid crystal panel 11 side) with screws. The control circuit board 12 includes a substrate made of paper phenol or glass epoxy resin. Electronic components for supplying various signals to the driver 17 are mounted on the substrate and traces (conductive lines), which are not illustrated, are formed and routed. One of ends (a first end) of the flexible circuit board 13 is electrically and mechanically connected to the control circuit board 12 via an anisotropic conductive film (ACF), which is not illustrated.

As illustrated in FIG. 2, the flexible circuit board 13 includes a base member made of synthetic resin material (e.g., polyimide-based resin) having an insulating property and flexibility. A member of traces, which are not illustrated, are formed on the base member. As described earlier, the first end of the flexible circuit board 13 with respect to the long direction is connected to the control circuit board 12 disposed on the back surface of the chassis 14a. The other one of the ends (a second end) of the flexible circuit board 13 connected to the array board 11b of the liquid crystal panel 11. The flexible circuit board 13 is folded to turn back and to have a U-shaped cross section in the liquid crystal display device 10. At the ends of the flexible circuit board 13 with respect to the long direction, sections of the traces are exposed and configured as terminals (not illustrated). The terminals are electrically connected to the control circuit board 12 and the liquid crystal panel 11. According to the configuration, the signals supplied by the control circuit board 12 are transmitted to the liquid crystal panel 11.

As illustrated in FIG. 1, the driver 17 is an LSI chip that includes a drive circuit therein. The driver 17 is configured to operate based on the signals supplied by the control circuit board 12, which is a signal source. The driver 17 is configured to process the signals supplied by the control circuit board 12, which is a signal source, to generate output signals, and output the output signals to the display area AA of the liquid crystal panel 11. The driver 17 has a horizontally-long rectangular shape (an elongated shape along a short edge of the liquid crystal panel 11) in a plan view. The driver 17 is directly mounted in the non-display area NAA of the liquid crystal panel 11 (on the array board 11b, which will be described later). Namely, the driver 17 is mounted with the chip-on-glass (COG) technology. The long direction of the driver 17 corresponds with the X-axis direction (the short direction of the liquid crystal panel 11) and the short direction of the driver 17 corresponds with the Y-axis direction (the long direction of the liquid crystal panel 11).

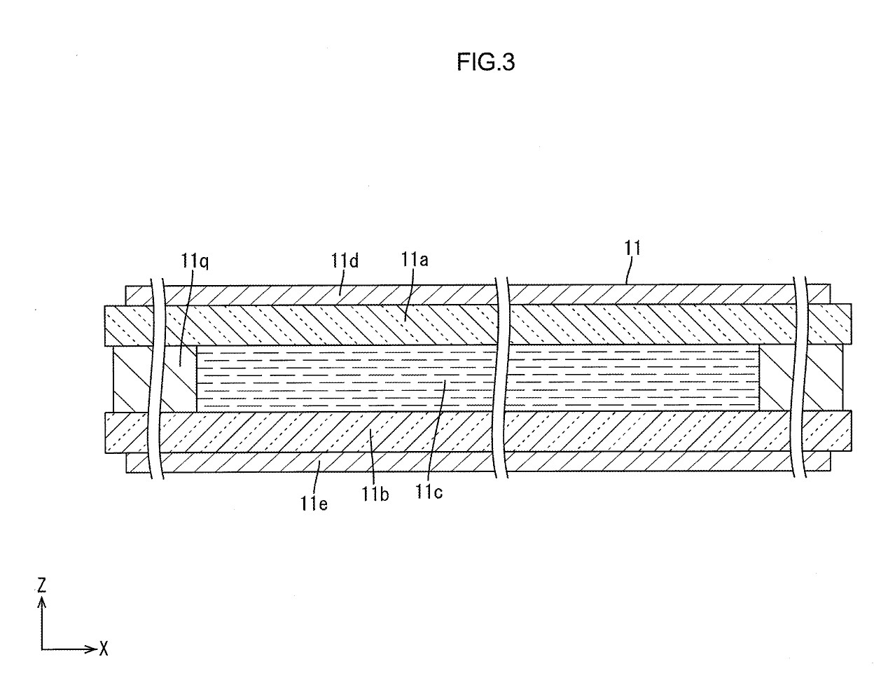

The liquid crystal panel 11 will be described. As illustrated in FIG. 3, the liquid crystal panel 11 includes at least a pair of the boards 11a and 11b, a liquid crystal layer 11c (a medium layer), and a sealing member 11q. The liquid crystal layer 11c is disposed in an internal space between the boards 11a and 11b. The liquid crystal layer 11c includes liquid crystal molecules that are substances having optical characteristics that vary according to application of an electric field. The sealing member 11q is disposed between the boards 11a and 11b to surround the liquid crystal layer 11c disposed in the internal space. The sealing member 11q seals the liquid crystal layer 11c while maintaining a cell gap in a size that corresponds with a thickness of the liquid crystal layer 11c. One of the boards 11a and 11b on the front side is the CF board 11a (a second board, a common board). The other one of the boards 11a and 11b on the rear side (the back side) is the array board 11b (a first board, an active matrix board). The CF board 11a and the array board 11b include glass substrates GS that are made of glass and various films that are formed in layered on inner surfaces of the glass substrates GS. The sealing member 11q is disposed in the non-display area NAA of the liquid crystal panel 11. The sealing member 11q has a vertically-long frame shape along the non-display area NAA in the plan view (the view in a normal direction to a plate surface of the array board 11b) (FIG. 2). Sections of the sealing member 11q disposed in three edge areas (non-mounting edge areas) other than the mounting area in which the driver 17 and the flexible circuit board 13 are located at the outermost in the non-display area NAA (FIG. 1). Polarizing plates 11d and 11e are attached to outer surfaces of the boards 11a and 11b, respectively.

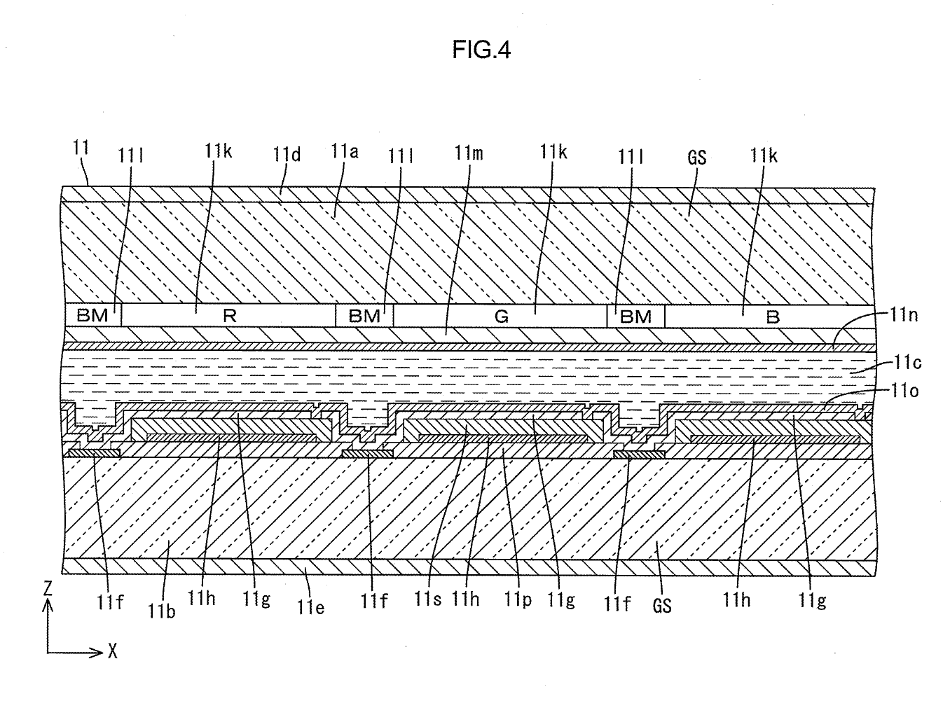

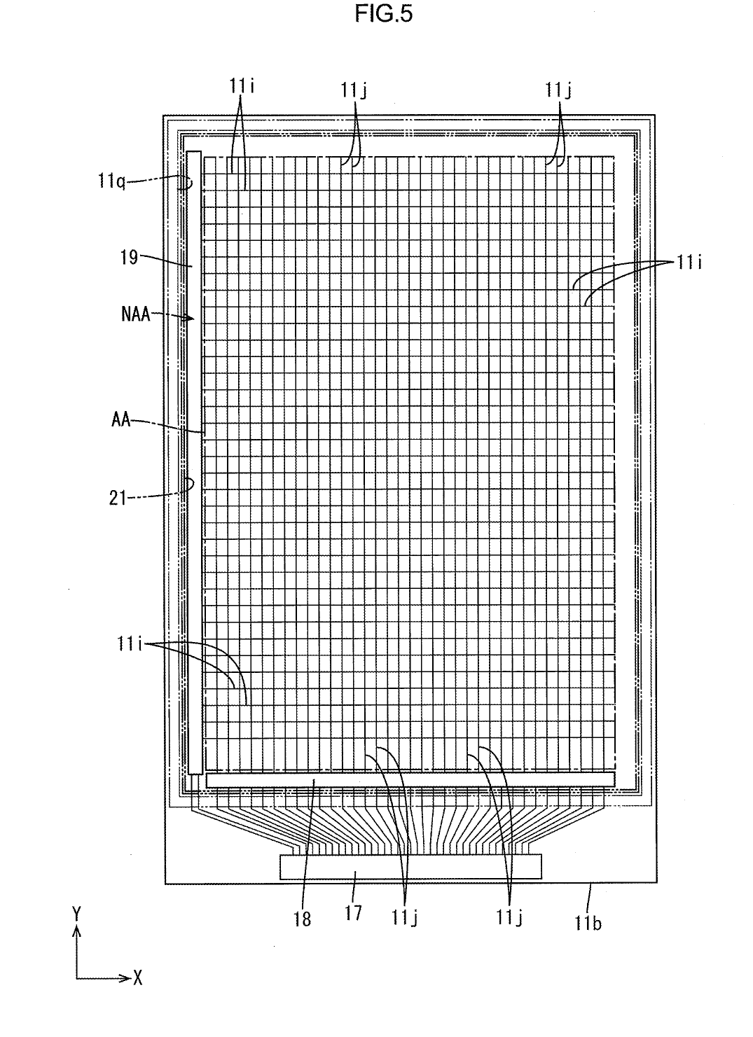

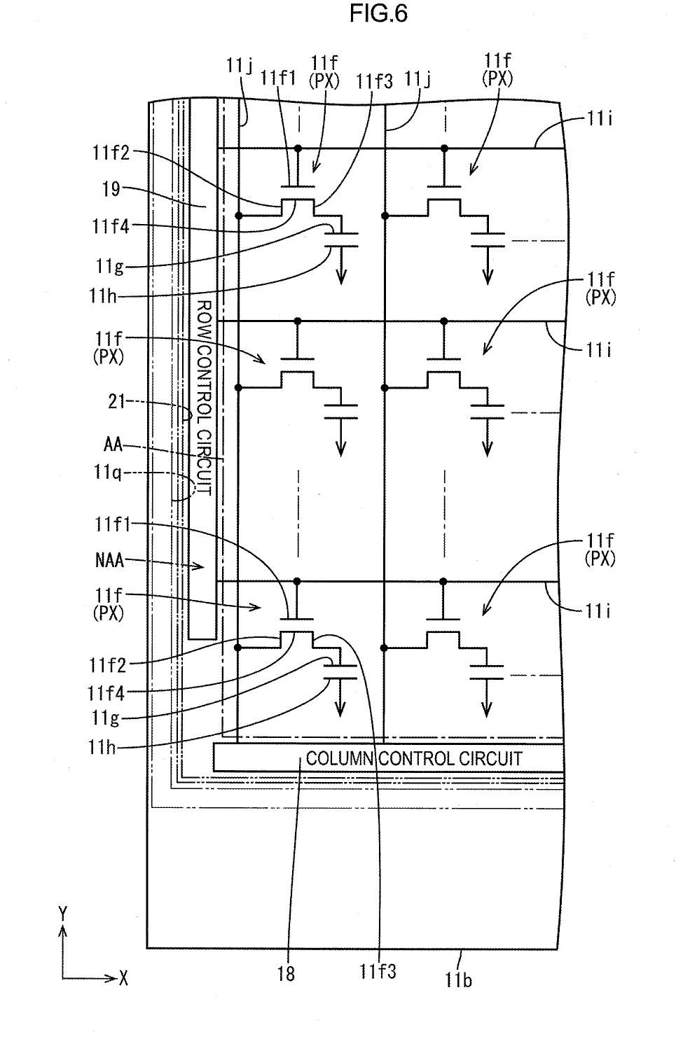

On an inner surface of the array board 11b (on a liquid crystal layer 11c side, an opposed surface that is opposed to the CF board 11a), as illustrated in FIGS. 4 and 6, thin film transistors (TFTs, display components) 11f which are switching components and pixel electrodes 11g are arranged in rows and columns (in a matrix). Gate lines 11i (scan lines) and source lines 11j (data lines, signal lines) are routed in a grid to surround the TFTs 11f and the pixel electrodes 11g. A gate insulating film 11p (a lower layer-side insulating film) is disposed between the gate lines 11i and the source lines 11j. The gate lines 11i and the source lines 11j are insulated from each other with the gate insulating film lip. The gate lines 11i and the source lines 11j are connected to gate electrodes 11f1 and source electrodes 11f2 of the TFTs 11f, respectively. The pixel electrodes 11g are connected to drain electrodes 11f3 of the TFTs 11f. The TFTs 11f are driven based on signals supplied to the gate lines 11i and the source lines 11j. The TFTs 11f are driven based on various signals supplied to the gate lines 11i and the source lines 11j. Application of voltages to the pixel electrodes 11g is controlled in accordance with the driving of the TFTs 11f. The TFTs 11f include channels 11f4 that connect the drain electrodes 11f3 to the source electrodes 11f2. An oxide semiconductor film is used to form the channels 11f4. The oxide semiconductor film of the channels 11f4 has electron mobility 20 to 50 times higher in comparison to an amorphous silicon thin material. Therefore, the TFTs 11f can be easily reduced in size to obtain an optimal amount of transmitted light through the pixel electrodes 11g (an aperture rate of display pixels). This configuration is preferable for increasing the definition and reducing the power consumption.

As illustrated in FIGS. 4 and 6, the pixel electrodes 11g are disposed in quadrilateral areas defined by the gate lines 11i and the source lines 11j. The pixel electrodes 11g are formed from a transparent electrode film (an upper layer-side transparent electrode film) made of indium tin oxide (ITO) or zinc oxide (ZnO). The pixel electrodes 11g are disposed over an insulating film 11s on an upper layer side relative to the insulating film 11s. The insulating film 11s includes contact holes CH at positions to overlap the drain electrodes 11f3 of the TFTs 11f, respectively. The pixel electrodes 11g are electrically connected to the drain electrodes 11f3 of the TFTs 11f via the contact holes CH. Common electrodes 11h are disposed under the insulating film 11s on a lower layer side relative to the insulating film 11s. The common electrodes 11h are formed from the transparent electrode film (the lower layer-side transparent electrode film) similarly to the pixel electrodes 11g. The common electrodes 11h are formed as a solid pattern. The array board 11b includes the pixel electrodes 11g and the common electrodes 11h. When a potential difference is created between the electrodes 11g and 11h, a fringe electric field (an oblique electric field) including a component along the plate surface of the array board 11b and a component in the normal direction to the plate surface of the array board 11b. The liquid crystal panel 11 operates in fringe field switching (FFS) mode that is an improved version of in-plane switching (IPS) mode. In this embodiment, an extending direction in which the gate lines 11i extend and an extending direction in which the source lines 11j extend correspond with the X-axis direction and Y-axis direction in the drawings, respectively.

As illustrated in FIG. 4, on the inner surface of the CF board 11a in the display area AA, color filters 11k are arranged at positions opposed to the pixel electrodes 11g on the array board 11b. The color filters 11k include red (R), green (G), and blue (B) color portions in three colors. The R color portions, the G color portions, and the B color portion are repeatedly arranged to form a matrix. The color portions (the pixels PX) of the color filters 11k arranged in the matrix are separated from one another with a light blocking portion 11l (a black matrix). With the light blocking portion 11l, color mixture of different colors of light rays that pass through the color portions is less likely to occur. The light blocking portion 11l is formed in a grid in the plan view. The light blocking portion 11l includes dividing sections and a frame section. The grid section has a grid shape in the plan view and separates the color portion from one another. The frame portion has a frame shape (a picture frame shape) in the plan view and surrounds the dividing sections from the peripheral sides. The grid section of the light blocking portion 11l is disposed to overlap the gate lines 11i and the source lines 11j in the plan view. The frame section of the light blocking portion 11l extends along the sealing member 11q and has a vertically-long rectangular shape in the plan view. An overcoat film 11m (a planarization film) is disposed on surfaces of the color filters 11k and the light blocking portion 11l. The overcoat film 11m is disposed under the color filters 11k and the light blocking portion 11l, that is, on the liquid crystal layer 11c side. On the surface of the overcoat film 11m, a bank portion 11r and board support portions (not illustrated) are formed from the same material. The bank portion 11r is for defining the forming area to form an alignment film 11n, which will be described later. The board support portions support the array board 11b to provide the cell gap. In the liquid crystal panel 11, each color potion of the color filter 11k and the pixel electrode 11g that is opposed to the color potion form a single pixel PX. The pixels PX include red pixels, green pixels, and blue pixels. The red pixels include the R color portions of the color filters 11k. The green pixels include the G color portions of the color filters 11k. The blue pixels include the B color portions of the color filters 11k. The pixels PX in three colors are repeatedly arranged along the row direction (the X-axis direction) on the plate surface of the liquid crystal panel 11 to form pixel lines. A number of the pixel lines are arranged along the column direction (the Y-axis direction). Namely, a number of the pixels PX are arranged in a matrix in the display area of the liquid crystal panel 11.

In layers of the boards 11a and 11b which are disposed on the innermost to contact the liquid crystal layer 11c, alignment films 11n and 11o are formed, respectively. The alignment films 11n and 11o are for orienting the liquid crystal molecules in the liquid crystal layer 11c. The alignment films 11n and 11o are made of polyimide. The alignment films 11n and 11o are formed in solid in at least sections of the boards 11a and 11b in an entire display area AA. The alignment films 11n and 11o are photo alignment films configured to orient the liquid crystal molecules in a direction in which light rays are applied by applying the light rays that are in a specific wavelength range (e.g., ultraviolet rays). The alignment film 11o that is disposed on the array board 11b side is disposed over the insulating film 11s on the front side to cover at least the surface of the insulating film 11s. The alignment film 11n that is disposed on the CF board 11a side is disposed over the overcoat film 11m on the rear side to cover at least the surface of the overcoat film 11m.

Next, the configuration of the array board 11b in the non-display area NAA will be described in detail. As illustrated in FIG. 5, in the non-display area NAA, a column control circuit 18 is disposed in a section of the array board 11b adjacent to a short edge of the display area AA and a row control circuit 19 is disposed in a section of the array board 11b adjacent to a long edge of the display area AA. The column control circuit 18 and the row control circuit 19 are configured to perform control for supplying the signals that are output by the driver 17 to the TFTs 11f. The column control circuit 18 and the row control circuit 19 are monolithically fabricated on the array board 11b with the oxide semiconductor film, which are the same semiconductor film of the channels 11f4 of the TFTs 11f, as a base. The column control circuit 18 and the row control circuit 19 include control circuits for controlling the supply of the output signals to the TFTs 11f. The control circuits in the column control circuit 18 and the row control circuit 19 include at least control TFTs (not illustrated) and traces 20 that are connected to the control TFTs. As illustrated in FIGS. 5 and 6, the column control circuit 18 and the row control circuit 19 (the traces 20) are disposed closer to the middle of the non-display area relative to the sealing member 11q, that is, closer to the display area AA. The column control circuit 18 and the row control circuit 19 do not overlap the sealing member 11q in the plan view. In FIGS. 5 and 6, the sealing member 11q is indicated by two-dashed chain lines. In a production process of the array board 11b, the control circuits of the column control circuit 18 and the row control circuit 19 are patterned on the array board 11b simultaneously with the patterning of the TFTs 11f by a known photolithography method.

As illustrated in FIG. 5, the column control circuit 18 is disposed adjacent to the short edge of the display area AA on the lower side in FIG. 5, that is, between the display area AA and the driver 17 with respect to the Y-axis direction. The column control circuit 18 is disposed in a horizontally-long rectangular area that extends in the X-axis direction. The column control circuit 18 is connected to the source lines 11j disposed in the display area AA. The column control circuit 18 includes a switching circuit (an RGB switching circuit) for distributing image signals that are included in the output signals from the driver 17 to the source lines 11j. Specifically, a large number of the source lines 11j are disposed on the array board 11b in the display area AA along the X-axis direction. The source lines 11j are connected to the respective TFTs 11f that are connected to the respective pixel electrodes 11g that form the R (red) pixels PX, the G (green) pixels PX, and the B (blue) pixels PX. The column control circuit 18 is configured to distribute the image signals from the driver 17 to the source lines 11j of R, G, and B through the switching circuit. The column control circuit 18 may include an auxiliary circuit such as a level shifter circuit and an ESD protection circuit.

As illustrated in FIG. 5, the row control circuit 19 is disposed adjacent to the long edge of the display area AA on the left side in FIG. 5. The row control circuit 19 is disposed in a vertically-long rectangular area that extends along the Y-axis direction. The row control circuit 19 is connected to the gate lines 11i that are disposed in the display area AA. The row control circuit 19 includes a scanning circuit that is configured to supply scan singles included in the output signals from the driver 17 to the gate lines 11i at predefined timing to scan the gate lines in sequence. Specifically, a large number of the gate lines 11i are arranged on the array board 11b in the display area AA along the Y-axis direction. The row control circuit 19 is configured to scan the gate lines 11i by supplying the control signals (scan signals) from the driver 17 to the gate lines from the gate line 11i at the uppermost to the gate line 11i at the lowermost in FIG. 5 in the display area AA through the scanning circuit. The row control circuit 19 includes a buffer circuit for amplifying the scan signals. The row control circuit 19 may include an auxiliary circuit such as a level shifter circuit and an ESD protection circuit. The column control circuit 18 and the row control circuit 19 are connected to the driver 17 via connecting traces, which are not illustrated, formed on the array board 11b.

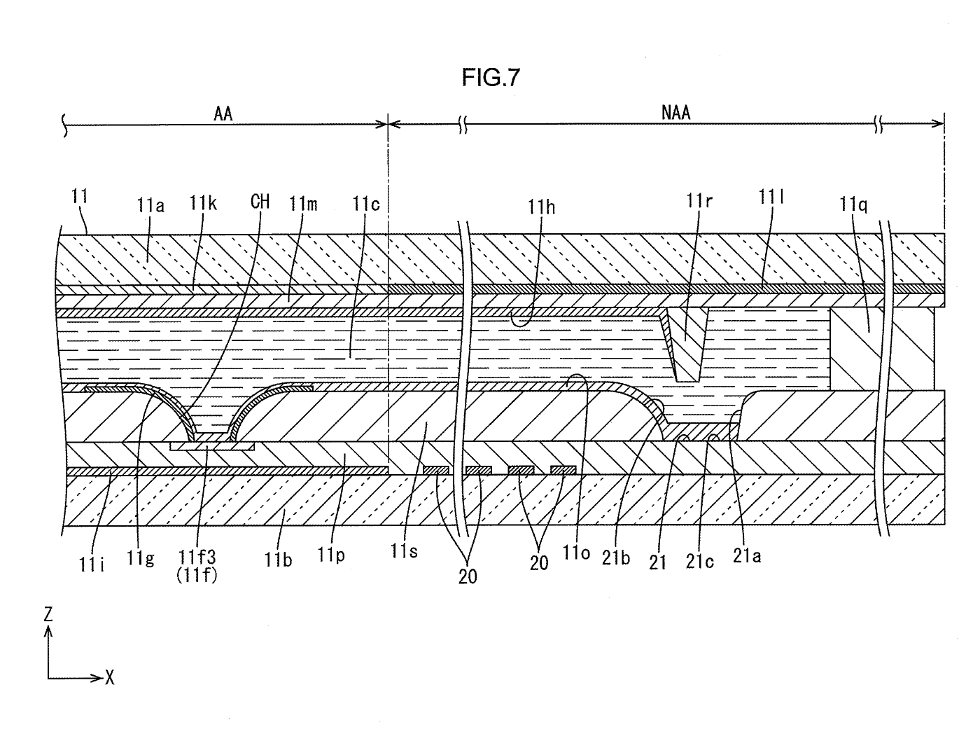

As illustrated in FIGS. 6 and 7, a film forming area control recess 21 for controlling the film forming are of the alignment film 11o is formed in sections of the array board 11b closer to the display area AA relative to the sealing member 11q. The film forming area control recess 21 is formed by recessing a section of the insulating film 11s. The film forming area control recess 21 has a frame shape to surround the display area AA in the plan view and an outline along an outline of the display area AA and an outline of the sealing member 11q. The film forming area control recess 21 is provided in the non-display area NAA and between the control circuits 18 and 19 and the sealing member 11q in the plan view. Therefore, the film forming area control recess 21 is less likely to exert an adverse effect on display quality of images that are displayed in the display area AA. The film forming area control recess 21 does not overlap the control circuits 18 and 19 (the traces 20) and the sealing member 11q in the plan view. In FIG. 7, the common electrodes 11h of the array board 11b are not illustrated.

As illustrated in FIG. 7, the film forming area control recess 21 is formed such that a first side surface 21a of an inner wall of the film forming area control recess 21 on the sealing member 11q side is angled relative to the normal direction to the plate surface of the array board 11b with an angle smaller than an angle of a second side surface 21b of the inner wall on an opposite side from the sealing member 11q side relative to the normal direction. Specifically, the film forming area control recess 21 includes at least a bottom surface 21c, the first side surface 21a, and the second side surface 21b. The bottom surface 21c is a substantially flat surface parallel to the X-axis direction and the Y-axis direction (the plate surface of the array board 11b). The first side surface 21a is closer to the sealing member 11q relative to the bottom surface 11c. The second side surface 11b is on an opposite side from the sealing member 11q side relative to the bottom surface 21c, that is, closer to the display area AA. The first side surface 21a and the second side surface 21b are angled relative to the bottom surface 21c and the normal direction. The film forming area control recess 21 has a depth (a dimension in the Z-axis direction) which is equal to the thickness of the insulating film 11s. Therefore, the bottom surface 21c is flush with a surface of the gate insulating film 11p on the front side. With the film forming area control recess 21, the insulating film 11s is divided into a middle section and a peripheral section that has a frame shape. The film forming area control recess 21 is disposed to overlap the bank portion 11r in the plan view.

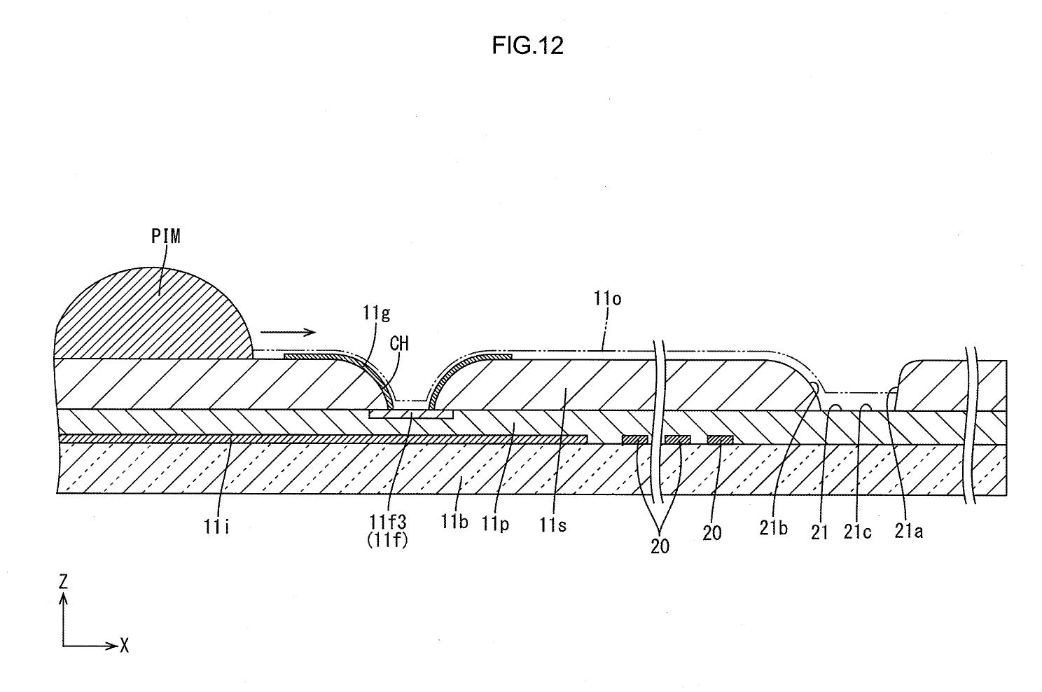

As illustrated in FIG. 7, the second side surface 21b is in a gently-curved arc in a cross-sectional view. A center of curvature of the second side surface 21b is set closer to the display area AA relative to the film forming area control recess 21 such that the second side surface 21b form an arc that bulges inward of the film forming area control recess 21. Tangent lines to the second side surface 21b are all angled relative to the bottom surface 21c and the normal direction to the bottom surface 21c. An average of angles of the tangent lines to the second side surface 21b relative to the normal direction of the bottom surface 21c plate surface of the array board 11b) is larger than an average of angles of tangent lines to the first side surface 21a relative to the normal direction. Namely, an average of angles of the tangent lines to the second side surface 21b relative to the bottom surface 21c is smaller than an average of angles of the tangent lines to the first side surface 21a relative to the bottom surface 21c. The second side surface 21b is a slope with a pitch that is gentler than that of the first side surface 21a. During the formation of the alignment film 11o in the production of the array board 11b, a material of the alignment film 11o having the flowability flow over the surface of the insulating film 11s from the display area AA side to the sealing member 11q side. The flowing material of the alignment film 11o is smoothly directed into the film forming area control recess 21 (see FIG. 12).

As illustrated in FIG. 7, a large section of the first side surface 21a projecting from the bottom surface 21c on a projecting base side is linearly sloped surface. A small section of the first side surface 21a on a projecting distal end side is formed in an arc. An angle of the sloped surface of the first side surface 21a relative to the normal direction to the bottom surface 21c is smaller than an angle of the second side surface 21b relative to the normal direction. Namely, an angle of the first side surface 21a relative to the bottom surface 21c is larger than an angle of the second side surface relative to the bottom surface 21c. The first side surface 21a is a slope with a pitch that is steeper than the second side surface 21b. Therefore, during the formation of the alignment film 11o, the material of the alignment film 11o flowing into the film forming area control recess 21 is less likely to flow over the first side surface 21a of the film forming area control recess 21 and spread toward the sealing member 11q. The alignment film 11o is less likely to overlap the sealing member 11q and thus fixing strength (adhesive strength) of the sealing member 11q to the array board 11b is maintained at a high level. Therefore, a defect such as bubbles in the liquid crystal layer 11c resulting from removal of the boards 11a and 11b is less likely to be produced. When a reduction of the frame size of the liquid crystal panel 11 progresses, it may be required to reduce a width of the film forming area control recess 21 to obtain proper level of the insulating performance of the insulating film 11s. In this case, a volume of the material of the alignment film 11o retained in the film forming area control recess 21 may decrease. Even in such a case, reach of the material of the alignment film 11o to the area that overlaps the sealing member 11q can be properly restricted. If the electrodes of the CF board 11a and the electrodes of the array board 11b are electrically connected via conducting particles that are made of metal such as gold and contained in the sealing member 11q, the electrodes of the array board 11b are not covered with the alignment film 11o because of the film forming area control recess 21 having the configuration described above. Therefore, the electrical connection between the electrodes and the conducing particles is less likely to be blocked.

The liquid crystal panel 11 in this embodiment has the configuration described above. Next, a method of producing the liquid crystal panel 11 will be described. The method of producing the liquid crystal panel 11 according to this embodiment includes at least an array board producing process (a first board producing process), a CF board producing process (a second board producing process), and a board bonding process. The array board producing process is for producing the array board 11b. The CF board producing process is for producing the CF board 11a. The board bonding process is for bonding the boards 11a and 11b. In the array board producing process and the CF board producing process, the various films are formed on the surfaces of the glass substrates GS included in the boards 11a and 11b and the films are patterned by a known lithography method. In the board bonding process, the sealing member 11q is formed on one of the boards 11a and 11b through drawing, the boards 11a and 11b are bonded together while the liquid crystal material of the liquid crystal layer 11c is dropped, and the sealing member 11q is cured to seal the liquid crystal layer 11c. Namely, the board bonding process includes a sealing member forming process for forming the sealing member 11q. In the array board producing process and the CF board producing process, it is preferable to use large-sized base boards (not illustrated) each including CF boards 11a or array boards 11b that are arranged in a matrix within a plate surface thereof. In this case, the base boards are divided into sections, that is, into the CF boards 11a or the array boards 11b.

The array board producing process includes at least an insulating film forming process, a film forming area control recess forming process, and an alignment film forming process. The insulating film forming process is for forming the insulating film 11s on the array board 11b. The film forming area control recess forming process is for forming the film forming area control recess 21 by recessing a section of the insulating film 11s on the array board 11b in which at least the sealing member 11q will be formed closer to the display area AA. The alignment film forming process is for forming the alignment film 11o to overlap the insulating film 11s of the array board 11b. In the film forming area control recess forming process, the film forming area control recess 21 is formed such that the angle of the first side surface 21a on the sealing member 11q side relative to the normal direction to the plate surface of the array board 11b is smaller than the angle of the second side surface 21b on the opposite side relative to the normal direction.

The film forming area control recess forming process will be described in detail. The film forming area control recess forming process includes at least an interim film forming area control recess forming process, a resist forming process, an etching process, and resist removal process. The interim film forming area control recess forming process is for forming an interim film forming area control recess 21IN in the insulating film 11s at a position closer to the display area AA relative to the position at which the sealing member 11q is formed. The interim film forming area control recess 21IN includes an interim first side surface 21aIN and the second side surface 21b angled relative to the normal direction to the plate surface of the array board 11b with angles that are about equal to each other. The resist forming process is for forming a resist R1 at a position to overlap the interim first side surface 21aIn of the interim film forming area control recess 21IN of the insulating film 11s to overlap the insulating film 11s. The resist R1 includes a hole Ra1. The etching process is for etching the insulating film 11s via the resist R1. The resist removal process is for removing the resist R1 from the insulating film 11s. The interim film forming area control recess forming process includes at least an exposing process for exposing the insulating film 11s using a photomask PM1 and a developing process for developing the insulating film 11s.

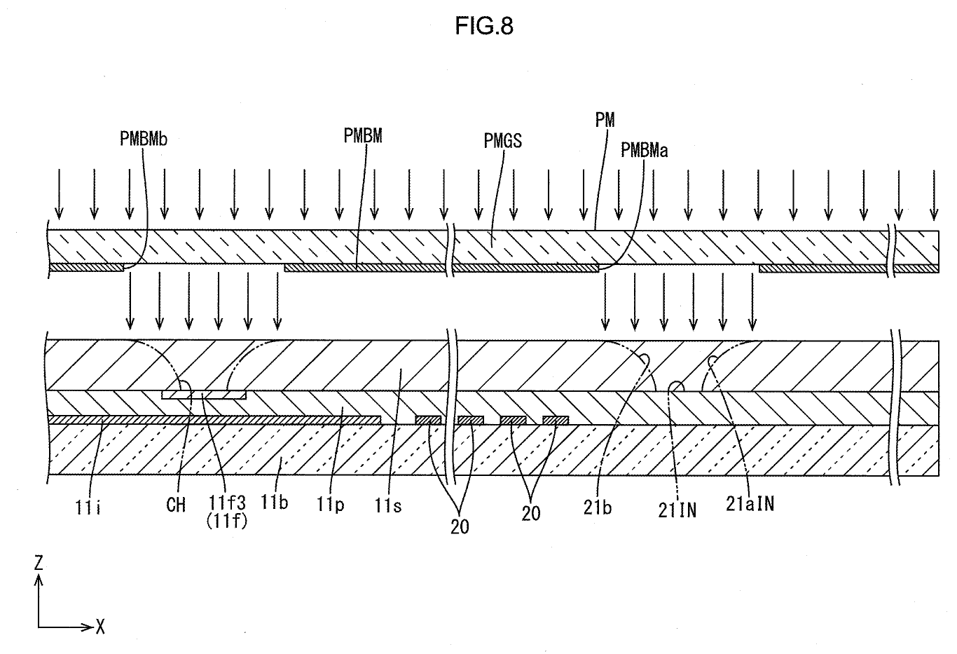

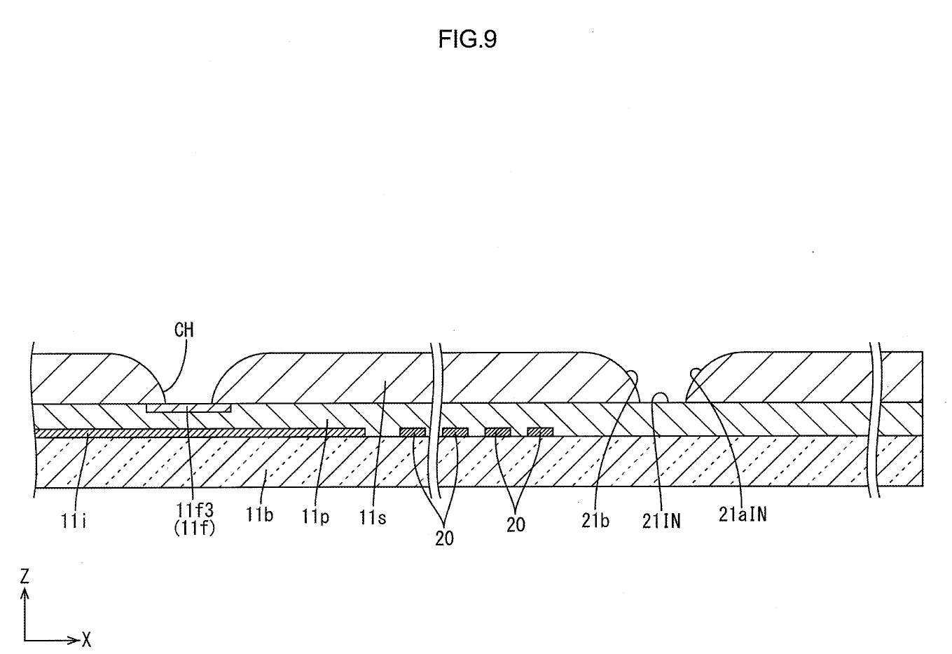

Detailed actions regarding the processes will be described in sequence. In the insulating film forming process included in the array board producing process, the insulating film 11s is formed using a positive-type photo-sensitive resin material. In the interim film forming area control recess forming process included in the film forming area control recess forming process and performed after the insulating film forming process, the insulating film 11s is exposed using a photomask PM (an exposing process) as illustrated in FIG. 8. The photomask PM includes a substantially transparent glass substrate PMGS and a light blocking film PMBM that is formed on a plate surface of the glass substrate PMGS and configured to block exposing light from a light source. The light blocking film PMBM of the photomask PM includes voids at positions corresponding to exposing positions on the insulating film 11s. Specifically, an interim film forming area control recess void PMBMa is formed at the position to overlap the position to form the interim film forming area control recess. Furthermore, a contact hole void PMBMb is formed at the position to overlap the position to form the contact hole CH. After an ultraviolet ray that is the exposing light from the light source is applied to the insulating film 11s via the photomask PM1 having such a configuration, the insulating film 11s is developed (the developing process). As illustrated in FIG. 9, the insulating film 11s that is developed includes the interim film forming area control recess 21IN that includes the interims first side surface 21aIn and the second side surface 21b and the contact holes CH. The contact holes CH are at the positions to overlap the drain electrodes 11f3. The interim film forming area control recess 21IN is temporarily formed on the insulating film 11s. The interim film forming area control recess 21IN is formed into the film forming area control recess 21 through the resist forming process, the etching process, and the resist removal process that are performed next.

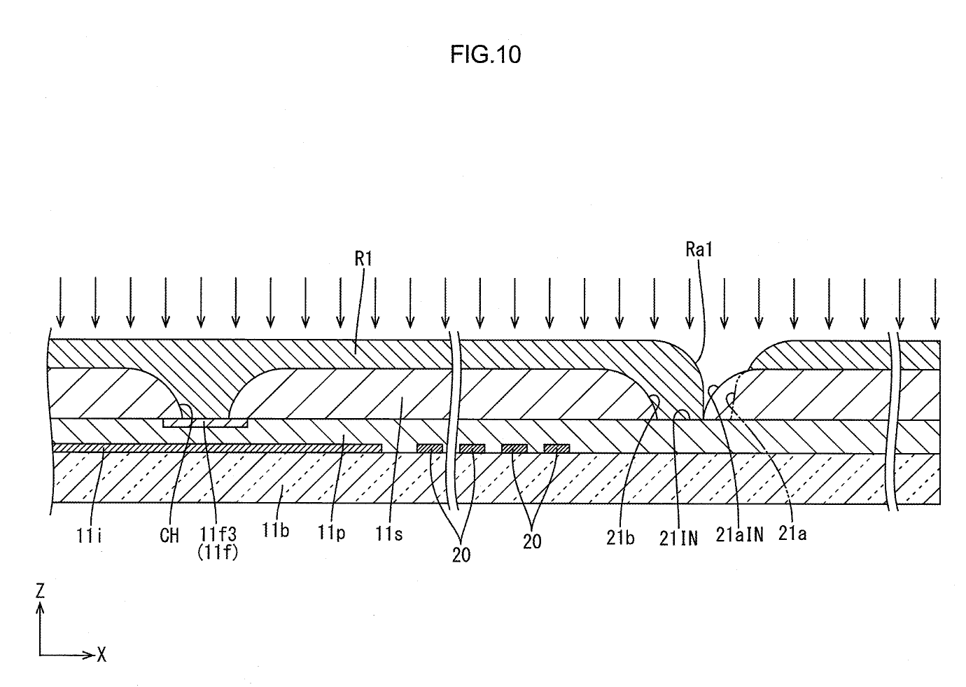

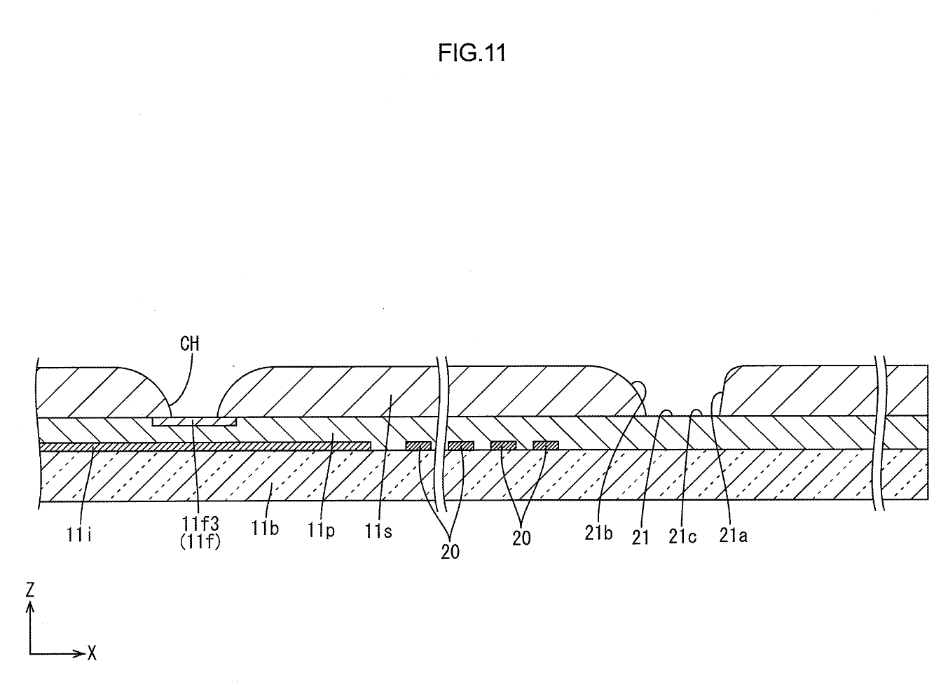

In the resist forming process, a film of the positive-type photosensitive material (photoresist) is formed on the surface of the insulating film 11s. The film is formed into the resist R1. The photosensitive material is exposed and developed via the photomask that is not illustrated. As a result, the resist R1 is formed. The photomask used here is configured to selectively expose a section of the photosensitive material overlapping the interim first side surface 21aIN of the interim film forming area control recess 21IN of the insulating film 11s. As illustrated in FIG. 10, the resist R1 that is formed through the resist forming process includes the hole Ra1 at the position overlapping the interim first side surface 21aIN of the interim film forming area control recess 21IN of the insulating film 11s. The second side surface 21b and the bottom surface 21c of the interim film forming area control recess 21IN are covered with the resist R1 but the interim first side surface 21aIN of the interim film forming area control recess 21IN is not covered with the resist R1. In the etching process, the insulating film 11s is etched via the resist R1 that includes the hole Ra1. In the etching process, so-called dry etching using a gas, for example, CF₄, SF₆, or O₂ is performed. The dry etching is performed to remove the insulating film 11s in a thickness direction thereof (the Z-axis direction) for an entire depth thereof. In the etching process, the interim first side surface 21aIn of the interim film forming area control recess 21IN of the insulating film 11s is selectively removed through the dry etching. In comparison to the second side surface 21b, the first side surface 21a indicated by the two-dashed chain line in FIG. 10 is steep and has a smaller angle relative to the normal direction to the plate surface of the array board 11b. When the resist removal process is performed afterward and the resist R1 is removed from the insulating film 11s, the insulating film 11s that includes the film forming area control recess 21 with the first side surface 21a and the second side surface 21b appears as illustrated in FIG. 11.

The alignment film forming process is performed after the film forming area control recess forming process described above is completed. In the alignment film forming process, liquid droplets PIM that are materials of the alignment film 11o are intermittently injected from a nozzle that is included in an inkjet device onto the insulating film 11s to land in the display area AA. As illustrated in FIG. 12, the liquid droplets PIM that are landed on the insulating film 11s in the display area AA flow and spread from landed positions and connect with the adjacent liquid droplets PIM that spread in the same manner to form the alignment film 11o. The liquid droplets PIM that are landed at the outermost positions in the display area AA may flow toward the non-display area NAA. Before the liquid droplets PIM reach the position to form the sealing member 11q, the liquid droplets PIM reach the film forming area control recess 21. The liquid droplets PIM that have reached the film forming area control recess 21 are directed into the film forming area control recess 21 by the second side surface 21b that is angled relative to the normal direction to the plate surface of the array board 11b with the larger angle and thus has the slope that is gentler in comparison to the first side surface 21a. The liquid droplets PIM that have flowed into the film forming area control recess 21 may flow over the film forming area control recess 21 and reach the position to form the sealing member 11q. However, the first side surface 21a of the film forming area control recess 21 is angled relative to the normal direction to the plate surface of the array board 11b and has the slope that is steeper in comparison to the second side surface 21b and thus the liquid droplets PIM are less likely to flow over the first side surface 21a. According to the configuration, the liquid droplets PIM are less likely to flow over the film forming area control recess 21 and reach the position to form the sealing member 11q. Because the alignment film 11o that is formed by baking the liquid droplets PIM that have spread out is less likely to be disposed at the position to overlap the sealing member 11q. Therefore, the fixing strength of the sealing member 11q can be maintained at a high level. The liquid droplets PIM that have flowed into the film forming area control recess 21 are retained in the film forming area control recess 21. When the board bonding process (the sealing member forming process) is performed after the alignment film forming process is completed, as illustrated in FIG. 7, the boards 11a and 11b are bonded together with the liquid crystal layer 11c and the sealing member 11q sandwiched between the boards 11a and 11b.

As described earlier, the liquid crystal panel 11 (the display panel) in this embodiment includes the pair of the boards 11a and 11b, the insulating film 11s, the sealing member, the insulating film 11s, the alignment film 11o, and the film forming area control recess 21. The boards 11a and 11b includes the plate surfaces that include sections disposed in the display area AA in which images are displayed and sections disposed in the non-display area NAA outside the display area AA. The boards 11a and 11b are opposed to each other with the internal space therebetween. The sealing member is disposed between the boards 11a and 11b in the non-display area NAA to surround the internal space and seal the internal space. The insulating film 11s is formed on the array board 11b (the first board) of the pair of the boards 11a and 11b. The alignment film 11o is disposes on the array board 11b to overlap the insulating film 11s at least in the display area AA. The film forming area control recess 21 is formed by recessing the section of the insulating film 11s at the position closer to the display area AA relative to the sealing member 11q on the array board 11b for controlling the forming area to form the alignment film 11o. The film forming area control recess 21 is configured such that at least the section of the first side surface 21a of on the sealing member 11q side is angled relative to the normal direction to the plate surface of the array board 11b with the smaller angle in comparison to the second side surface on the opposite side.

Because the alignment film 11o is disposed at least in the display area AA, the material of the alignment film 11o having the flowability is supplied to the array board 11b in the display area AA to form the alignment film 11o. The material flows over the surface of the insulating film 11s on the array board 11b to spread. As a result, the alignment film 11o is formed over the surface of the insulating film 11s. If the material of the alignment film 11o supplied to the display area AA flows toward the sealing member 11q in the non-display area NAA, the material of the alignment film 11o flows into the film forming area control recess 21 that is formed by recessing the section of the insulating film 11s at the position closer to the display area AA relative to the sealing member 11q on the array board 11b. The second side surface 21b of the film forming area control recess 21 on the opposite side from the sealing member 11q side is angled relative to the normal direction to the plate surface of the array board 11b with the larger angle in comparison to the first side surface 21a. Therefore, the material of the alignment film 11o having the flowability can be properly directed into the film forming area control recess 21. In contrast, the first side surface 21a of the film forming area control recess 21 on the sealing member 11q side is angled relative to the normal direction to the plate surface of the array board 11b with the smaller angle in comparison to the second side surface 21b. Therefore, the material of the alignment film 11o directed into the film forming area control recess 21 does not flow over the film forming area control recess 21 and reach the position to overlap the sealing member 11q. According to the configuration, the alignment film 11o is less likely to overlap the sealing member 11q and thus the fixing strength of the sealing member 11q relative to the array board 11b can be maintained at the high level. Even if the width of the film forming area control recess 21 is reduced due to the reduction in the frame size, flow of the material of the alignment film 11o to reach the position to overlap the sealing member 11q can be properly restricted.

The film forming area control recess 21 is disposed in the non-display area NAA. Therefore, the film forming area control recess 21 is less likely to exert an adverse effect on the display quality of the images displayed in the display area AA.

Furthermore, the traces 20 are disposed in the array board 11b in the non-display area NAA to overlap the insulating film 11s on the opposite side from the alignment film 11o side. In the configuration in which the traces 20 are disposed on the array board 11b in the non-display area NAA to overlap the insulating film 11s on the opposite side from the alignment film 11o side, it tends to be difficult to form the film forming area control recess 21 with a sufficient width because a proper level of the insulating ability of the insulating film 11s for the traces 20 is required. Because at least the section of the first side surface 21a of the film forming area control recess 21 is angled relative to the normal direction to the plate surface of the array board 11b with the smaller angle in comparison to the second side surface 21b, the forming area to form the alignment film 11o is properly controlled even if the width of the film forming area control recess 21 is not sufficient.

The method of producing the liquid crystal panel 11 in this embodiment includes at least the insulating film forming process, the film forming area control recess forming process, the alignment film forming process, and the sealing member forming process. In the insulating film forming process, the insulating film 11s is formed on the array board 11b of the pair of the boards 11a and 11b. The plate surfaces of the boards 11a and 11b include the sections disposed in the display area AA in which the images are displayed and in the non-display area NAA outside the display area AA. The boards 11a and 11b are opposed to each other with the internal space therebetween. The internal space is sealed with the sealing member 11q that is disposed in the non-display area NAA to surround the internal space. The film forming area control recess forming process is for forming the film forming area control recess 21 for controlling the forming area to form the alignment film 11o by recessing the section of the insulating film of the array board 11b closer to the display area AA relative to at least the position to form the sealing member 11q. In the film forming area control recess forming process, the film forming area control recess 21 is formed such that at least the section of the first side surface 21a on the sealing member 11q side is angled relative to the normal direction to the plate surface of the array board 11b with the smaller angle in comparison to the second side surface 21b on the opposite side. In the alignment film forming process, the alignment film 11o is formed to overlap the insulating film 11s of the array board 11b . In the sealing member forming process, the sealing member 11q is formed between the boards 11a and 11b.

In the insulating film forming process, the insulating film 11s is formed on the array board 11b of the pair of the boards 11a and 11b. In the film forming area control recess forming process, the film forming area control recess 21 for controlling the forming area to form the alignment film 11o is formed by recessing the section of the insulating film 11s of the array board 11b closer to the display area AA relative to at least the position to form the sealing member 11q. In the alignment film forming process, the alignment film 11o is formed to overlap the insulating film 11s of the array board 11b. In the sealing member forming process, the sealing member 11q is formed between the boards 11a and 11b.

In the alignment film forming process, the material of the alignment film 11o having the flowability is supplied to the section of the array board 11b in the display area AA. The material flows on the surface of the insulating film 11s on the array board 11b to spread. As a result, the alignment film 11o is formed to overlap the surface of the insulating film 11s. If the material of the alignment film supplied to the display area AA flows toward the position to form the sealing member in the non-display area NAA, the material of the alignment film 11s flows into the film forming area control recess 21 that is formed by recessing the section of the insulating film 11s at the position closer to the display area AA relative to the sealing member 11q on the array board 11b. The film forming area control recess 21 is formed such that the second side surface 21b on the opposite side from the sealing member 11q side is angled relative to the normal direction to the plate surface of the array board 11b with the larger angle in comparison to the first side surface 21a in the film forming area control recess forming process. Therefore, the material of the alignment film 11o having the flowability is properly directed into the film forming area control recess 21. In the film forming area control recess forming process, the film forming area control recess 21 is formed such that the first side surface 21a on the sealing member 11q side is angled relative to the normal direction to the plate surface of the array board 11b with the smaller angle in comparison to the second side surface 21b. Therefore, the material of the alignment film 11o directed into the film forming area control recess 21 is less likely to flow over the film forming area control recess 21 and reach the position to overlap the sealing member 11q. According to the configuration, the alignment film 11o is less likely to overlap the sealing member 11q and thus the fixing strength of the sealing member 11q relative to the array board 11b can be maintained at the high level. Even if the width of the film forming area control recess 21 is reduced due to the reduction in frame size, the flow of the material of the alignment film 11o to the position to overlap the sealing member 11q can be properly restricted during the forming of the alignment film 11o.

The film forming area control recess forming process includes at least the interim film forming area control recess forming process, the resist forming process, the etching process, and the resist removal process. In the interim film forming area control recess forming process, the interim film forming area control recess 21IN is temporarily formed in at least the section of the insulating film 11s at the position closer to the display area AA relative to the positon to form the sealing member 11q. The interim film forming area control recess 21IN includes the interim first side surface 21a and the second side surface 21b that are angled relative to the normal direction to the plate surface of the array board 11b with the angles equal to each other. In the resist forming process, the resist R1 is formed to overlap the insulating film 11s. The resist R1 includes at least the hole Ra1 at the position to overlap the interim first side surface 21aIN of the interim film forming area control recess 21IN of the insulating film 11s. In the etching process, the insulating film 11s is etched via the resist R1. In the resist removal process, the resist R1 is removed from the insulating film 11s.

In the interim film forming area control recess forming process that is included in the film forming area control recess forming process, the interim film forming area control recess 21IN is temporarily formed at least in the section of the insulating film closer to the display area AA relative to the position to form the sealing member 11q. The interim film forming area control recess 21IN includes the interim first side surface 21aIN and the second side surface 21b that are angled relative to the normal direction to the plate surface of the array board 11b with the angles that are equal to each other. In the resist forming process that is performed next, the resist R1 is formed to overlap the insulating film 11s. The resist R1 includes at least the hole Ra1 at the position to overlap the interim first side surface 21aIn of the interim film forming area control recess 21IN of the insulating film. In the etching process, the section of the insulating film 11s overlapping the hole Ra1 of the resist R1 is selectively etched. As a result, the film forming area control recess 21 that includes the first side surface 21a is formed. The first side surface 21a is angled relative to the normal direction to the plate surface of the array board 11b with the smaller angle in comparison to the second side surface 21b. The resist R1 is removed in the resist removal process afterward.

In the etching process, the dry etching is performed. Therefore, the insulating film 11s can be processed with higher accuracy in comparison to the wet etching.

### Second Embodiment

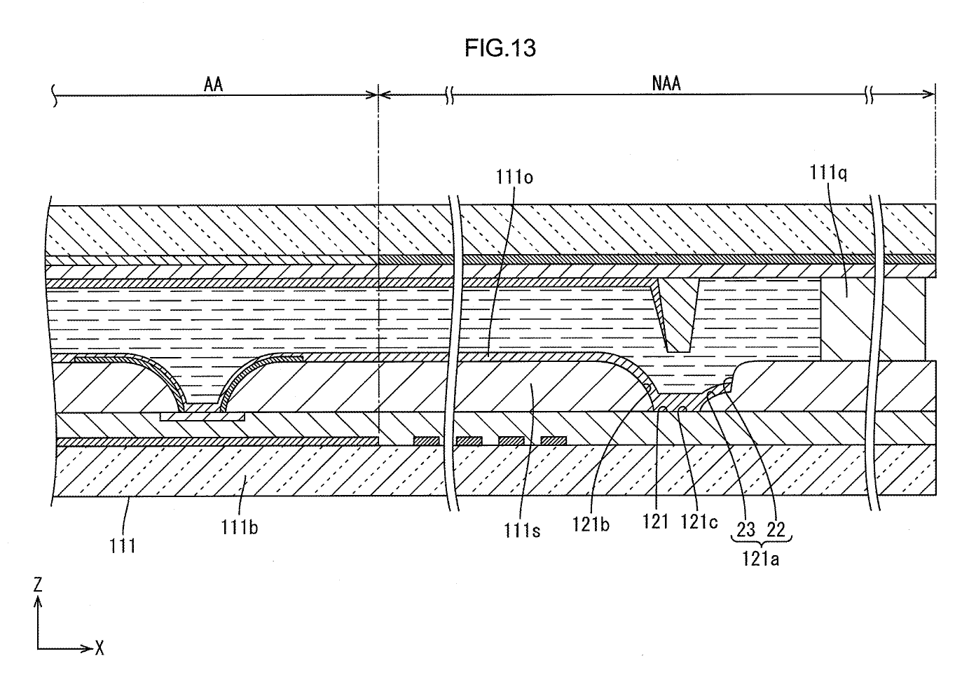

A second embodiment of the present invention will be described with reference to FIGS. 13 to 15. The second embodiment includes a film forming area control recess 121 that includes a first side surface 121a in a shape that is altered. Configurations, functions, and effects similar to those of the first embodiment will not be described.

As illustrated in FIG. 13, the film forming area control recess 121 in this embodiment includes the first side surface 121a and a second side surface 121b. The first side surface 121a includes a steep slope 22 and a gentle slope 23. The steep slope 22 is angled relative to a normal direction to a plate surface of an array board 111b (a bottom surface 121c) with a smaller angle in comparison to the second side surface 121b. The gentle slope 23 is disposed closer to the display area AA in comparison to the steep slope 22. The gentle slope 23 is angled relative to the normal direction of the plate surface of the array board 111b with a larger angle in comparison to the steep slope 22. The steep slope 22 is a substantially linearly sloped surface. The angle of the steep slope 22 relative to the normal direction to the plate surface of the array board 111b is smaller than the angle of the second side surface 121b and the angle of the gentle slope 23 relative to the normal direction. Namely, the angle of the steep slope 22 relative to the plate surface of the array board 111b is larger than the angle of the second side surface 121b and the angle of the gentle slope 23 relative to the normal direction. The slope of the steep slops 22 is steeper then the slope of the second side surface 121b and the slope of the gentle slope 23. The gentle slope 23 has a cross section that is gently curved arc. The center of curvature of the gentle slope 23 is located closer to a sealing member 111q relative to the film forming area control recess 121. The gentle slope 23 bulges toward an inner side of the film forming area control recess 121 to form an arc. Tangent lines to the gentle slope 23 are angled relative to the plate surface of the array board 111b and the normal direction to the plate surface. An average of the angles of the tangent lines to the normal direction to the plate surface of the array board 111b is larger than the angle of the steep slope 22 and the angle of the second side surface 121b. Namely, the average of the angles of the tangent lines to the gentle slope relative to the plate surface of the array board 111b is smaller than the angle of the steep slope 22 and the angle of the second side surface 121b. The slope of the gentle slope 23 is gentler than the slope of the steep slope 22 and the slope of the second side surface 121b.

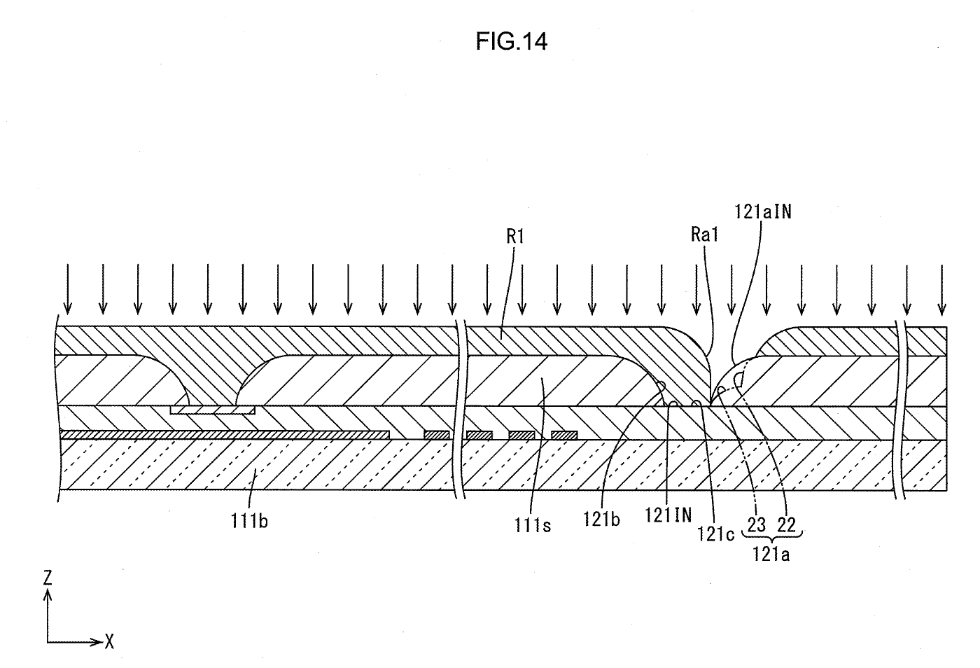

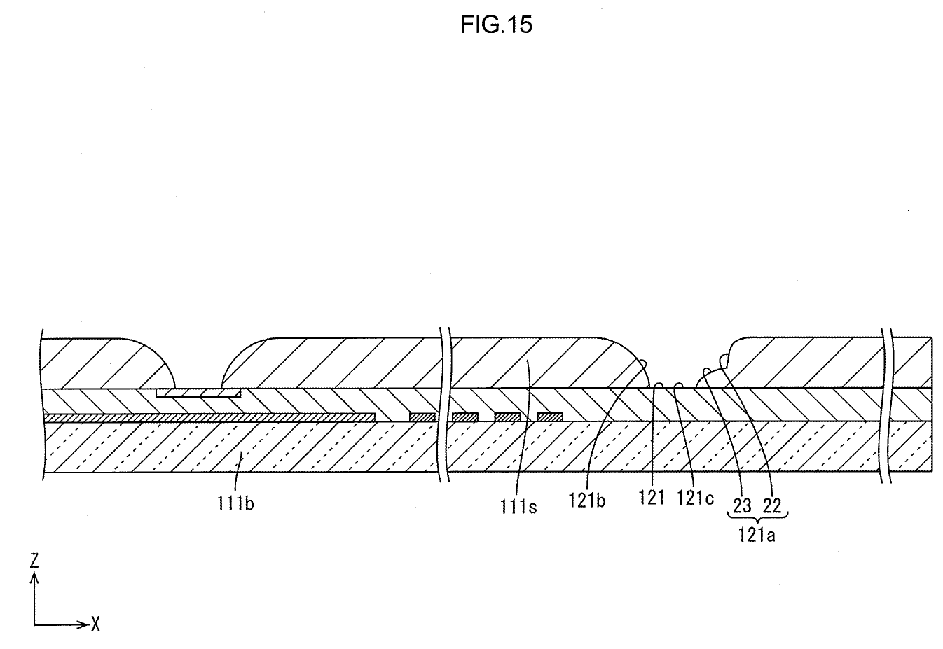

A film forming area control recess forming process for forming the film forming area control recess 121 in an insulating film 111s is performed as follows. After an interim film forming area control recess 121IN is formed in the insulating film 111s through an interim film forming area control recess forming process, a resist forming process is performed to form the resist R1 including the hole Ra1 at a position to overlap an interim first side surface 121aIN. The dry etching is performed to remove the insulating film 111s in a thickness direction thereof in the middle of depth thereof vis the hole Ra1 of the resist R1 as illustrated in FIG. 14. The interim first side surface 121aIN is processed into a shape such that the angle varies in the middle. The first side surface 121a that includes the steep slope 22 and the gentle slope 23 is formed. When the resist removal process is performed afterward and the resist R1 is removed from the insulating film 111s, the insulating film 111s that includes the film forming area control recess 121 with the first side surface 121a and the second side surface 121b appears as illustrated in FIG. 15.

After the film forming area control recess forming process is performed as described above, an alignment film forming process is performed. As illustrated in FIG. 13, a material of an alignment film 111o having flowability (liquid droplets) flows into the film forming area control recess 121 during flowing and spreading thereof from the display area AA side to the sealing member 11q side. The material of the alignment film 111o that has flowed into the film forming area control recess 121 may flow over the gentle slope 23 of the first side surface 121a which is disposed closer to the display area AA relative to the steep slope 22 and angled relative to the normal direction to the plate surface of the array board 111b with the larger angle in comparison to the steep slope 22. However, the flow of the material of the alignment film 111o is restricted by the steep slope 22 that is angled relative to the normal direction to the plate surface of the array board 111b with the smaller angle in comparison to the second side surface 121b. In comparison to the configuration in which the film forming area control recess 21 has the steep slope for the entire area as in the first embodiment described earlier, the material of the alignment film 111o is more likely to flow over the gentle slope 23. A larger amount of the material of the alignment film 111o is retained in the film forming area control recess 121.

As described above, according to a liquid crystal panel 111 in this embodiment, the film forming area control recess 121 includes the first side surface 121a that includes at least the steep slope 22 and the gentle slope 23. The steep slope 22 is angled relative to the normal direction to the plate surface of the array board 111b with the smaller angle in comparison to the second side surface 121b. The gentle slope 23 is disposed closer to the display area AA relative to the steep slope 22 and angled relative to the normal direction to the plate surface of the array board 111b with the larger angle in comparison to the steep slope 22. When the material of the alignment film 111o is directed into the film forming area control recess 121 via the second side surface 121b during the formation of the alignment film 111o, the material may flow over the gentle slope 23 of the first side surface 121a which is disposed closer to the display area AA relative to the steep slope 22 and angled relative to the normal direction to the plate surface of the array board 111b with the larger angle in comparison to the steep slope 22. However, the flow of the material is restricted by the steep slope 22 that is angled relative to the normal direction to the plate surface of the array board 111b with the smaller angle in comparison to the second side surface 121b. In comparison to a configuration in which the film forming area control recess includes the steep slope 22 for the entire area, the material of the alignment film 111o is more likely to flow over the gentle slope 23. Therefore, a larger amount of the material of the alignment film 111o is retained in the film forming area control recess 121.

### Third Embodiment

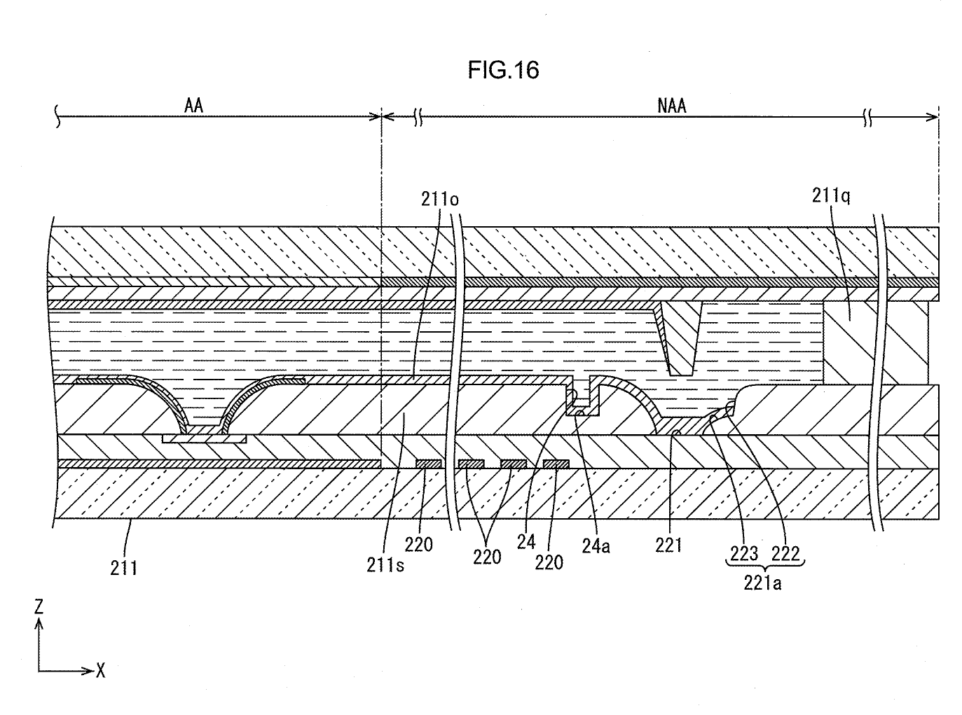

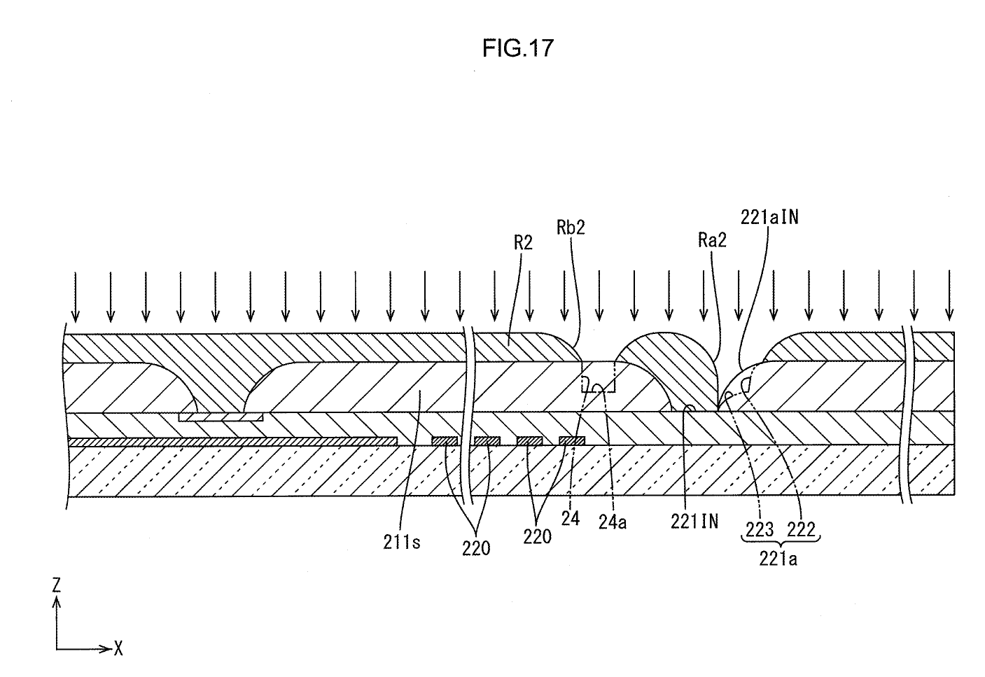

A third embodiment of the present invention will be described with reference to FIGS. 16 to 18. The third embodiment includes a second film forming area control recess 24 in addition to the configuration of the second embodiment. Configurations, functions, and effects similar to those of the first and the second embodiments will not be described.

As illustrated in FIG. 16, the second film forming area control recess 24 is formed such that a section of an insulating film 211s in this embodiment, on an opposite side from a sealing member 211b side, that is, a display area AA side relative to a film forming area control recess 221 is recessed. The second film forming area control recess 24 has a frame shape in a plan view along the film forming area control recess 221. In an alignment film forming process, a material of an alignment film 211c having flowability (liquid droplets) flows into the second film forming area control recess 24 before reaching the film forming area control recess 221 during flowing and spreading of the material from the display area AA side to a sealing member 211q side. A flow rate of the material of an alignment film 211o flowing over a surface of the insulating film 211s is reduced. The flow of the material of the alignment film to a position to overlap the sealing member 211q is further properly restricted.

As illustrated in FIG. 16, the second film forming area control recess 24 is formed in the insulating film 211s to be shallower than the film forming area control recess 221. The second film forming area control recess 24 is disposed closer to the display area AA relative to the film forming area control recess 221. In this embodiment, the second film forming area control recess 24 overlaps sections of traces 220. Because the second film forming area control recess 24 is shallower than the film forming area control recess 221, this configuration is preferable for ensuring insulating performance of the insulating film 211s for the traces 220. The second film forming area control recess 24 has a height relative to a bottom surface 24a is aligned with a height of a boundary between a gentle slope 223 and a steep slope 222 of a first side surface 221a of the film forming areas control recess 221.

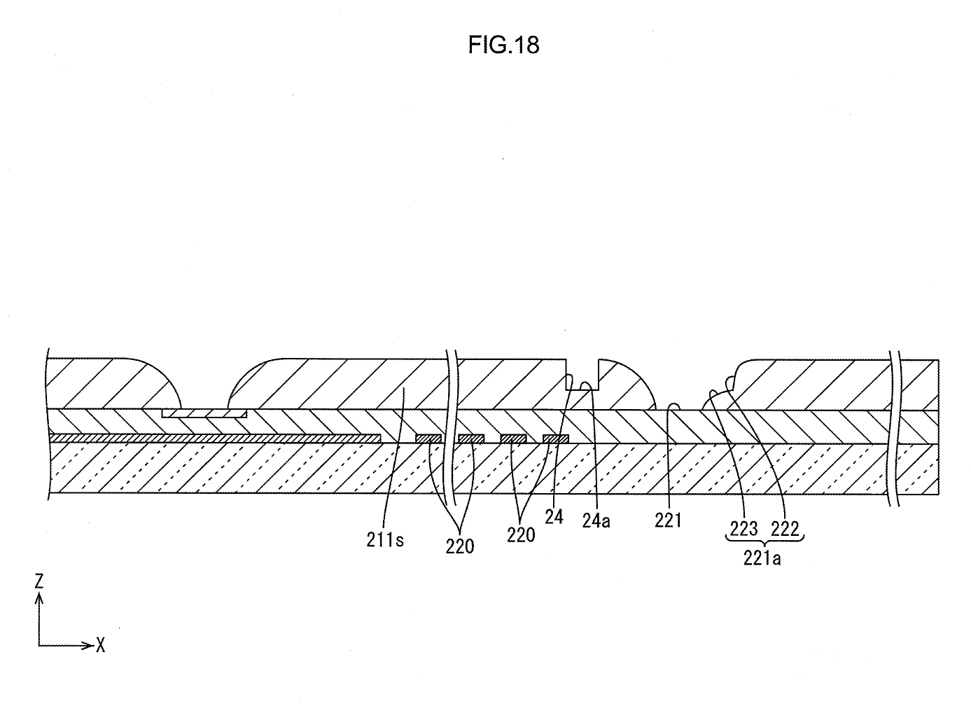

The second film forming area control recess 24 having such a configuration and the film forming area control recess 221 are formed in the insulating film 211s in the film forming area control recess forming process. Specifically, when an interim film forming area control recess 221IN is formed in the insulating film 211s through an interim film forming area control recess forming process, a resist forming process is performed afterward to form a resist R2 that includes a first hole Ra2 and a second hole Rb2 as illustrated in FIG. 17. The first hole Ra2 is located at a position to overlap an interim first side surface 221aIN. The second hole Rb2 is located at a position to overlap a position to form the second film forming area control recess 24. In an etching process that is performed afterward, the dry etching is performed to remove the insulating film 211s in a thickness direction thereof in the middle of depth thereof via the first hole Ra2 and the second hole Rb2 of the resist R2. The interim first side surface 221aIn is processed to have an angle that is altered in the middle through the dry etching via the first hole Ra2. As a result, the first side surface 221a that includes the steep slope 222 and the gentle slope 223 is formed. The second film forming area control recess 24 that is shallower than the film forming area control recess 221 is formed in the insulating film 211s through the dry etching via the second hole Rb2. A resist removal process is performed afterward to remove the resist R2 from the insulating film 211s. As illustrated in FIG. 18, the insulating film 211s in which the film forming area control recess 221 and the second film forming area control recess 24 are formed appears. Through the same etching process, the film forming area control recess 221 and the second film forming area control recess 24 are formed in the insulating film 211s. In comparison to forming of the film forming area control recess 221 and the second film forming area control recess 24 in different etching processes, cost and takt time can be reduced. Because the film forming area control recess 221 and the second film forming area control recess 24 are formed through the same etching process, the bottom surface 24a of the second film forming area control recess 24 and a boundary between the gentle slope 223 and the steep slope 222 are at about the same height.

As described above, according to a liquid crystal panel 211 in this embodiment, the second film forming area control recess 24 is formed in the insulating film 211s on the opposite side from the sealing member 211q side relative to the film forming area control recess 221 such that the section of the insulating film 211s is recessed. According to the configuration, the material of the alignment film 211o having the flowability flows into the second film forming area control recess 24 before reaching the film forming area control recess 221. The flow of the material of the alignment film 211o to the position to overlap the sealing member 211q can be further properly restricted.

The second film forming area control recess 24 is shallower than the film forming area control recess 221. Because the second film forming area control recess 24 is formed on the opposite side from the sealing member 211q side relative to the film forming area control recess 221 to be shallower than the film forming area control recess 221, this configuration is preferable for securing the insulating performance of the insulating film 211s.

The second film forming area control recess 24 is formed in the insulating film 211s on the opposite side from the sealing member 211q side relative to the film forming area control recess 221 such that the section of the insulating film 211s is recessed. Furthermore the height at which the bottom surface of the second film forming area control recess 24 is disposed is aligned with the height at which the boundary between the gentle slope 223 and the steep slope 222 is disposed. According to the configuration, the material of the alignment film 211o having the flowability flows into the second film forming area control recess 24 before reaching the film forming area control recess 221. The reach of the material of the alignment film 211o to the position to overlap the sealing member 211q can be further properly restricted. According the above-described configuration, when sections of the insulating film 211s are etched to form the film forming area control recess 221 and the second film forming area control recess 24, the film forming area control recess 221 and the second film forming area control recess 24 can be formed simultaneously in the same etching process. Therefore, the cost and the takt time can be reduced.

### Fourth Embodiments

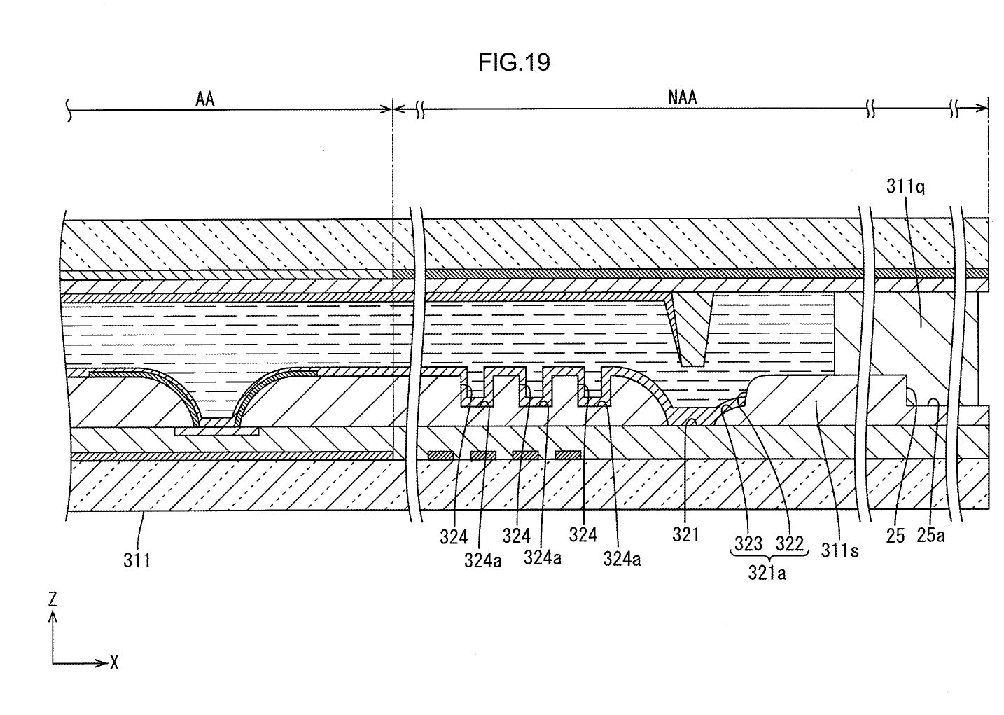

A fourth embodiment will be described with reference to FIGS. 19 to 21. The fourth embodiment includes second film forming area control recesses 324, the number of which is different from that of the third embodiment and a sealing member 311q that includes a step 25. Configurations, functions, and effects similar to those of the first to the third embodiments will not be described.

As illustrated in FIG. 19, the second film forming area control recesses 324 in this embodiment are disposed at intervals in an insulating film 311s. Specifically, three second film forming area control recesses 324 are formed in the insulating film 311s. The first second film forming area control recess 324 is located the closest to a film forming area control recess 321. The second second film forming area control recess 324 is located closer to the display area AA in comparison to the first second film forming area control recesses 324. The third second film forming area control recess 324 is located further closer to the display area AA in comparison to the second second film forming area control recess 324. Bottom surfaces 324a of the second film forming area control recesses 324 are at about the same level.

As illustrated in FIG. 19, the insulating film 311s includes the step 25 at a position to overlap the sealing member 311q in a plan view. Specifically, the step 25 is formed by recessing a section of the insulating film 311s. The step 25 is disposed to overlap a peripheral section of the sealing member 311q in the plan view. A bottom surface 25a of the step 25 is at about the same level with the bottom surfaces 324a of the second film forming area control recesses 324. According to the insulating film 311s that includes the step 25 having such a configuration, a contact area of the sealing member 311q with the insulating film 311s is larger in comparison to the first to the third embodiments. Therefore, the fixing strength of the sealing member 311q relative to the insulating film 311s becomes higher. Through processing performed on the insulating film 311s to form the step 25, the step 25 has a higher surface roughness. Therefore, the fixing strength of the sealing member 311q relative to the insulating film 311s becomes even higher.

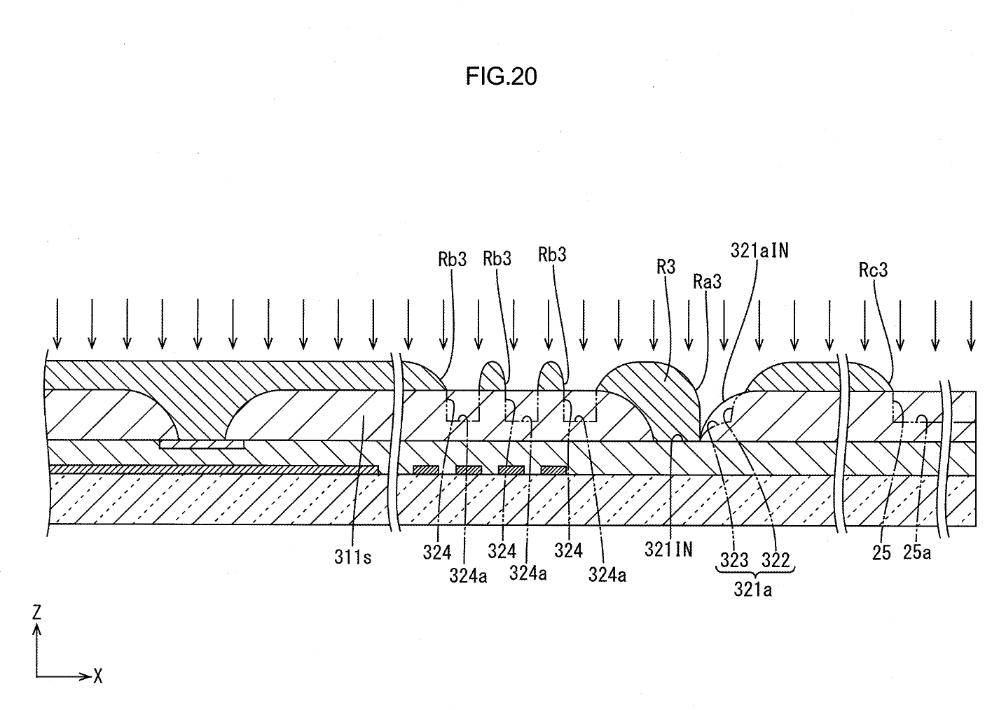

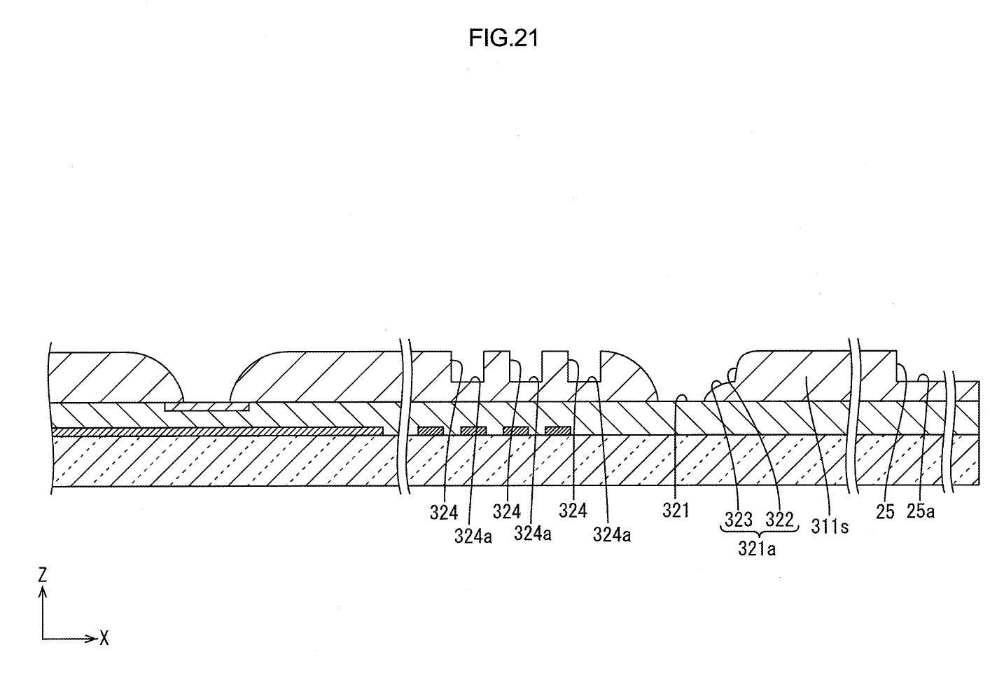

The second film forming area control recesses 324 and the step 25 having such configurations and the film forming area control recess 321 are formed in the insulating film 311s in the film forming area control recess forming process. Specifically, after an interim film forming area control recess 321IN is formed in the insulating film 311s through an interim film forming area control recess forming process, a resist forming process is performed to form a resist R3. As illustrated in FIG. 20, the resist R3 includes a first hole Ra3, three second holes Rb3, and a third hole Rc3. The first hole Ra3 are located at a position to overlap an interim first side surface 321aIN. The second holes Rb3 are located at positions to overlap positions at which the second film forming area control recesses 324 are formed. The third hole Rc3 is located at a position to overlap a position at which the step 25 is formed. In an etching process that is performed afterward, the dry etching is performed to remove the insulating film 311s in a thickness direction thereof in the middle of depth thereof via the first hole Ra3, the second holes Rb3, and the third hole Rc3 of the resist R3. The interim first side surface 321aIN is processed to have an angle that is altered in the middle through the dry etching via the first hole Ra3. As a result, a first side surface 321a that includes a steep slope 322 and a gentle slope 323 is formed. Three second film forming area control recessed 324 that are shallower than the film forming area control recess 321 are formed in the insulating film 311s through the dry etching via the second holes Rb3. Furthermore, the step 25 is formed in the insulating film 311s through the dry etching via the third hole Rc3. As illustrated in FIG. 21, when the resist R3 is removed from the insulating film 311s in a resist removal process that is performed afterward, the insulating film 311s that includes the film forming area control recess 321, the second film forming area control recesses 324, and the step 25 appears. The film forming area control recess 321, the second film forming area control recesses 324, and the step 25 are formed in the insulating film 311s through the same etching process. In comparison to those formed through different etching processes, cost and takt time can be reduced. Because the film forming area control recess 321, the second film forming area control recesses 324, and the step 25 are formed through the same etching process, the bottom surface 25a of the step 25, the bottom surfaces 324a of the second film forming area control recesses 324, and a boundary between the gentle slope 223 and the steep slope 322 are at about the same height. Furthermore, the step 25 is formed by processing the insulating film 311s through the dry etching as described earlier and thus the step 25 has higher surface roughness in comparison to non-etched areas.

As described above, a liquid crystal panel 311 in this embodiment includes the step 25 formed in the insulating film 311s at the position to overlap the sealing member 311q. In comparison to a configuration in which a section of an insulating film which overlaps the sealing member 311q is flat, a contact area of the sealing member 311q with the insulating film 311s is larger. Therefore, the fixing strength of the sealing member 311q relative to the insulating film 311s is higher. Because the step 25 has higher surface roughness through the process that is performed on the insulating film 311s to form the step 25, the fixing strength of the sealing member 311q relative to the insulating film 311s becomes even higher.

### Fifth Embodiment

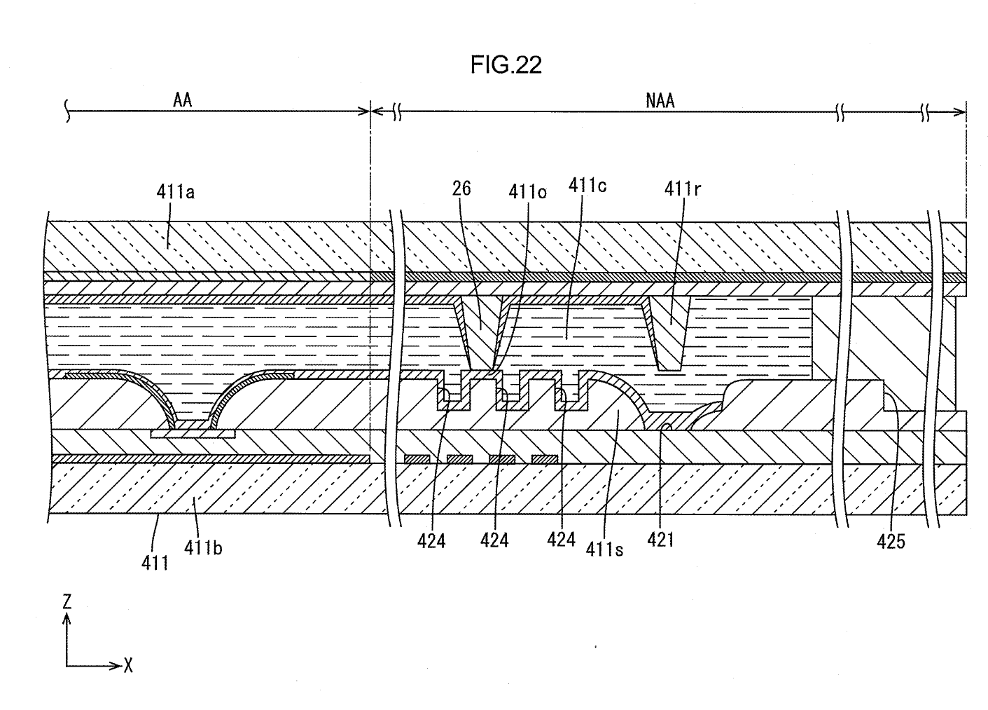

A fifth embodiment will be described with reference to FIG. 22. The fifth embodiment includes a board support 26 in addition to the configuration of the fourth embodiment. Configurations, functions, and effects similar to those of the first to the fourth embodiments will not be described.

As illustrated in FIG. 22, a CF board 411a in this embodiment includes the board support 26 that protrude toward an array board 411b to support the array board 411b. The board support 26 is disposed not to overlap a film forming area control recess 421, second film forming area control recesses 424, and a step 425. Specifically, the board support 26 is disposed between the adjacent second film forming area control recesses 424 in an insulating film 411s such that a distal end surface of the board support 26 contact an alignment film 411o on an array board 411b side. According to the configuration, a distance between the CF board 411a and the array board 411b, that is, a thickness of a liquid crystal layer 411c (a cell gap) can be stably maintained. The distal end surface of the board support 26 is substantially flush with a distal end surface of a bank portion 411r. The board support is formed simultaneously with the bank portion 411r in the CF board producing process.

As described above, a liquid crystal panel 411 in this embodiment includes the CF board 411a (a second board) which includes the board support 26 that protrudes toward the array board 411b to support the array board 411b. The board support 26 is disposed not to overlap the film forming area control recess 421 and the second film forming area control recesses 424. According to the configuration, the board support 26 of the CF board 411a is less likely to overlap the film forming area control recess 421 and the second film forming area control recesses 424. Therefore, the array board 411b can be further properly supported by the board support 26 and a height of an internal space can be properly maintained.

### Sixth Embodiment

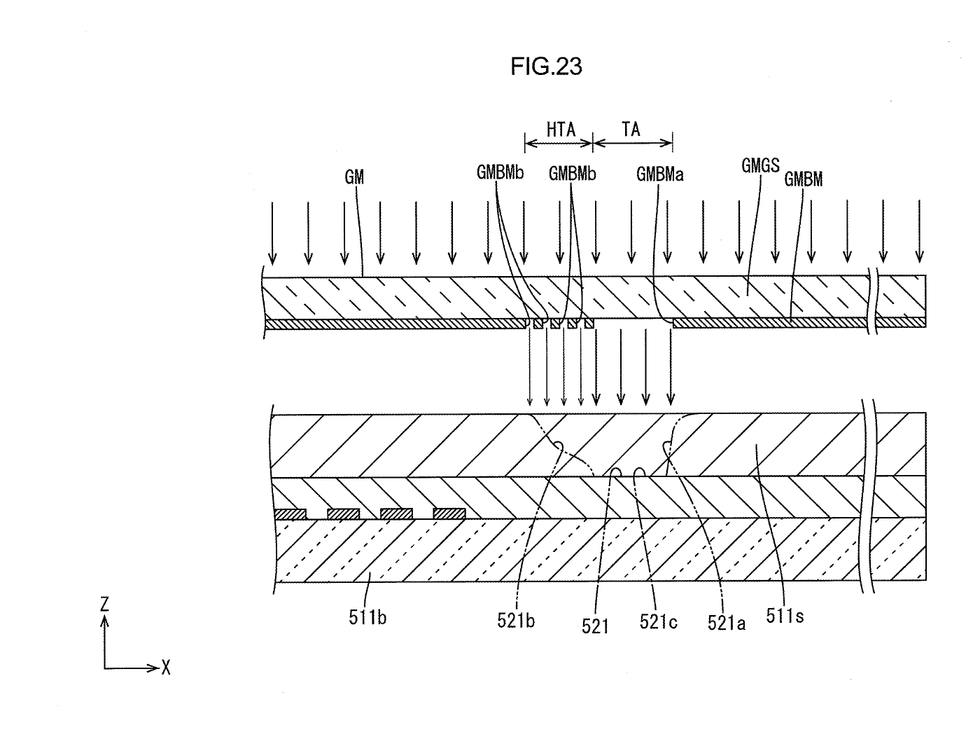

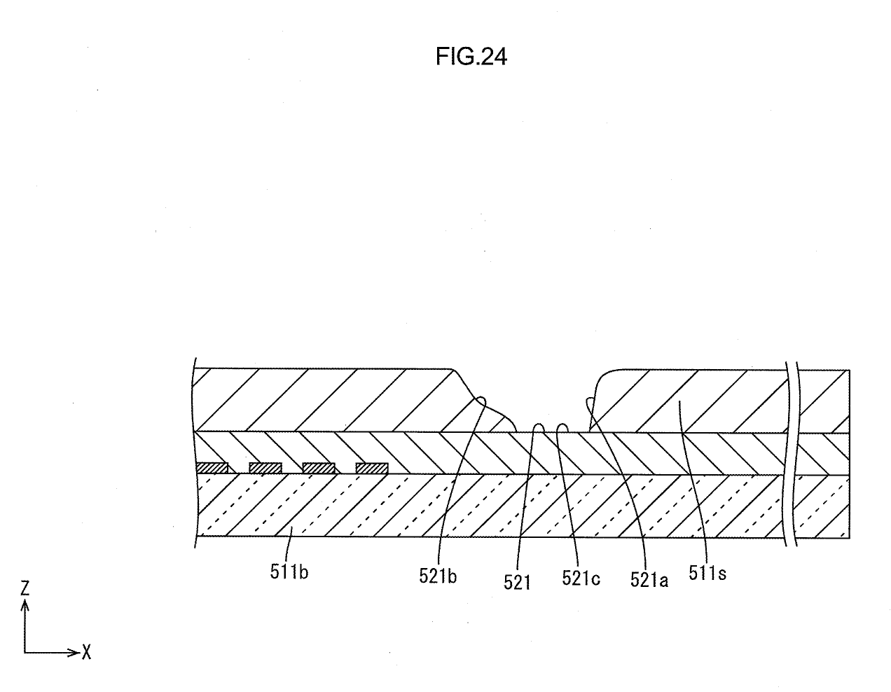

A sixth embodiment will be described with reference to FIGS. 23 and 24. The sixth embodiment includes a film forming area control recess forming process that is different from the first embodiment. Configurations, functions, and effects similar to those of the first embodiment will not be described.

In a method of producing a liquid crystal panel in this embodiment, an insulating film 511s is formed from a positive-type photosensitive material in an insulating film forming process. Furthermore, a grey tone mask GM is used as a photomask in a film forming area control recess forming process. As illustrated in FIG. 23, the grey tone mask GM includes a transparent glass substrate GMGS and a light blocking film GMBM that is formed on a plate surface of the glass substrate GMGS and configured to block exposing light from a light source. The light blocking film GMBM includes a hole GMBMa that is greater than definition of a exposure device and slits GMBMb that are less than the definition of the exposure device. The bole GMBMa is formed at a position to overlap positions to form a bottom surface 521c and a first side surface 521a of a film forming area control recess 521 in the insulating film 511s. A similar hole is formed at a position to overlap a position to form a contact hole, which is not illustrated. The hole GMBMa is defined as a transmissive area TA having transmissivity of 100% to pass the exposing light. The slits GMBMb are formed at positions to overlap a position to form a second side surface 521b of the film forming area control recess 521 of the insulating film 511s. Namely, the slits GMBMb are disposed at the positions adjacent to the hole GMBMa on the display area AA side. Multiple slits are disposed at intervals. A group of the slits GMBMb is defined as a semi-transmissive area HTA having transmissivity in a range from 10% to 70% to pass the exposing light.

The film forming area control recess forming process using the grey tone mask GM having such a configuration includes an exposing process and a developing process. In the exposing process, the insulating film 511s is exposed via the grey tone mask GM. In the developing process, the exposed insulating film 511s is developed. In the exposing process, when ultraviolet rays that form the exposing light from the light source is applied to the insulating film 511s via the grey tone mask GM, an amount of applied light is larger in a section of the insulating film 511s overlapping the hold GMBMa (the transmissive area TA) and an amount of applied light is smaller in a section of the insulating film 511s overlapping the group of the slits GMBMb (the semitransmissive area HTA). When the developing process is performed afterward, the film forming area control recess 521 is formed in the insulating film 511s as illustrated in FIG. 24. The film forming area control recess 521 includes the first side surface 521a, the bottom surface 521c, and the second side surface 521b. The first side surface 521a is angled relative to a normal direction to a plate surface of an array board 511b with a smaller angle. The bottom surface 521c is substantially flat. The second side surface 521b is angled relative to the normal direction to the plate surface of the array board 511b with a larger angle. In a single exposing process, the film forming area control recess 521 that includes the first side surface 521a and the second side surface 521b, the angles of which relative to the normal direction to the plate surface of the array board 511b are different from each other, is formed. An effect of reducing time that is required for the production can be achieved.

As described above, the method of producing the liquid crystal panel in this embodiment includes the insulating film forming process and a film forming area control recess forming process. In the insulating film forming process, the insulating film 511s is formed using the photosensitive material in the insulating film forming process. The film forming area control recess forming process includes at least the exposing process and the developing process. In the exposing process, the insulating film 511s is exposed using the grey tone mask GM as a photomask. The grey tone mask GM includes the transmissive area TA and the semitransmissive area HTA. In the exposing process, the grey tone mask GM is used such that the semitransmissive area HTA is disposed at the position to overlap the position to form the second side surface 521b of the film forming area control recess 521. In the developing process, the insulating film 511s is developed.

In the insulating film forming process, the insulating film 511s is formed using the photosensitive material. In the exposing process includes in the film forming area control recess forming process, the insulating film 511s is exposed using the grey tone mask GM that includes the transmissive area TA and the semitransmissive area HTA. In the developing process that is performed afterward, the insulating film 511s is developed. As a result, the film forming area control recess 521 is formed. The grey tone mask GM used in the exposing process is disposed such that at least the semitransmissive area HTA is disposed at the position to overlap the position to form the second side surface 521b of the film forming area control recess 521. Therefore, the angle of the second side surface 521b of the film forming area control recess 521 of the insulating film 511s that is exposed and developed relative to the normal direction to the plate surface of the array board 511b is smaller in comparison to the first side surface 521. When the positive-type photosensitive material is used, the transmissive area TA of the grey tone mask GM is disposed at the positon to overlap at least the position to form the first side surface 521a of the film forming area control recess 521 of the insulating film 511s. With the transmissive area TA disposed at the position, the angle of the first side surface 521a of the film forming area control recess 521 of the exposed and developed insulating film 511s relative to the normal direction to the plate surface of the array board 511b is smaller in comparison to the second side surface 521b. As described above, in the single exposing process, the film forming area control recess 521 that includes the first side surface 521a and the second side surface 521b having the angles relative to the normal direction to the plate surface of the array board 511b different from each other is formed. Time that is required for the production can be reduced.

### Seventh Embodiment

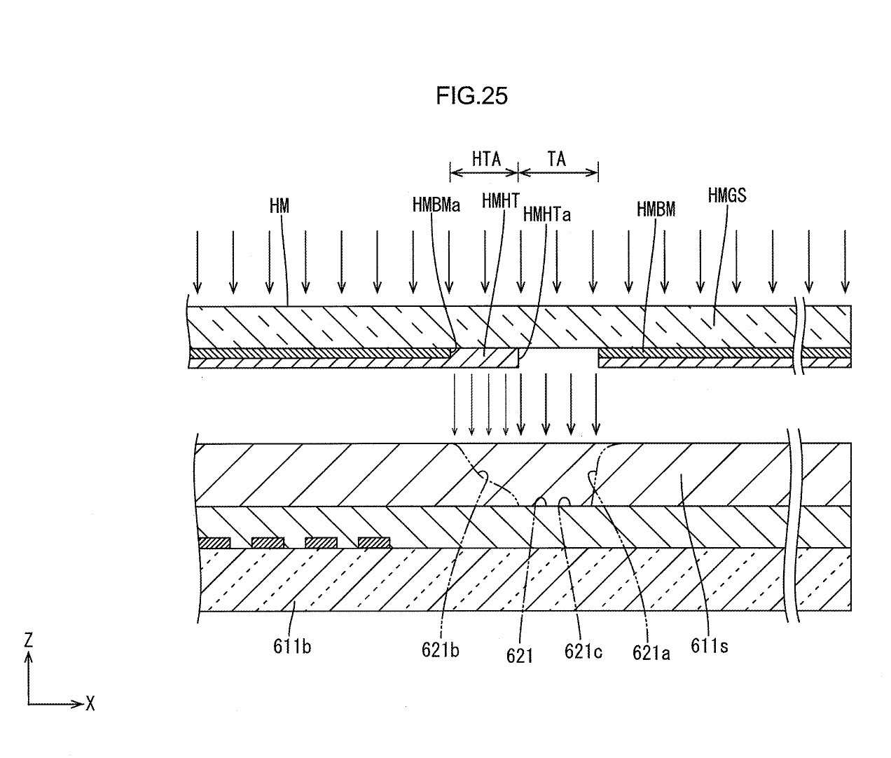

A seventh embodiment will be described with reference to FIG. 25. The seventh embodiment includes a film forming area control recess forming process in which a halftone mask HM is used as a photomask, which is different from the sixth embodiment. Configurations, functions, and effects similar to those of the sixth embodiment will not be described.

In a method of producing a liquid crystal panel in this embodiment, an insulating film 611s is formed using a positive-type photosensitive material in an insulating film forming process and the halftone mask HM is used as a photomask in the film forming area control recess forming process. As illustrated in FIG. 25, the halftone mask HM includes a transparent glass substrate HMGS, a light blocking film HMBM, and a semitransmissive film HMHT. The light blocking film HMBM is formed on a plate surface of the glass substrate HMGS and configured to block exposing light from a light source. The semitransmissive film HMHT is formed on the plate surface of the glass substrate HMGS and configured to pass the exposing light from the light source at a predefined level of transmissivity. The light blocking film HMBM has transmissivity of substantially 0% to pass the exposing light. The light blocking film HMBM includes a hole HMBMa that overlap about an entire area in which a film forming area control recess 621 will be formed. The semitransmissive film HMHT is formed over the light blocking film HMBM on an opposite side from a glass substrate HMGS side. The transmissivity of the semitransmissive film HMHT to pass the exposing light is in a range from 10% to 70%. The hole HMHTa is formed in the semitransmissive film HMHT at a position to overlap positions to form the first side surface 621b and a bottom surface 621c. Namely, in a section of the glass substrate HMGS of the halftone mask HM overlapping the second side surface 621b of the film forming area control recess 621, the light blocking film HMBM does not exist and only the semitransmissive film HMHT exist. The section in which the semitransmissive film exits is defined as a semitransmissive area HTA having transmissivity to pass the exposing light in a range from 10% to 70%. The semitransmissive area HTA is an area of the hole HMBMa of the light blocking film HMBM which does not overlap the hole HMHTa of the semitransmissive film HMHT. The hole HMHTa of the semitransmissive film HMHT is defined as a transmissive area TA having transmissivity of about 100% to pass the exposing light.

The film forming area control recess forming process in which the halftone mask HM having such a configuration includes an exposing process and a developing process. In the exposing process, the insulating film 611s is exposed via the halftone mask HM. In the developing process, the exposed insulating film 611s is developed. In the exposing process, when ultraviolet rays that form the exposing light from the light source are applied to the insulating film 611s via the halftone mask HM, an amount of applied light is larger in a section of the insulating film 611s which overlaps the hole HMHTa of the semitransmissive film HMHT (the transmissive area TA). In a section of the insulating film 611s which overlaps the area of the hole HMBMa of the light blocking film HMBM which does not overlap the hole HMHTa of the semitransmissive film HMHT (the semitransmissive area HTA), an amount of applied light is smaller. When the developing process is performed afterward, the film forming area control recess 621 that includes a first side surface 621a, the bottom surface 621c, and the second side surface 621b is formed in the insulating film 611s (see FIG. 24). The angle of the first side surface 621a relative to a normal direction to a plate surface of an array board 611b is smaller. The bottom surface 621c is substantially flat. The angle of the second side surface 621b relative to the normal direction to the plate surface of the array board 611b is larger. In the single exposing process, the film forming area control recess 621 that includes the first side surface 621a and the second side surface 621b, the angles of which relative to the normal direction to the plate surface of the array board 611b are different from each other, is formed. Therefore, an effect of reducing time that is required for the production can be achieved.

As described above, according to the method of producing the liquid crystal panel in this embodiment, the insulating film 611s is formed using the photosensitive material in the insulating film forming process. The film forming area control recess forming process includes the exposing process and the developing process. In the exposing process, the insulating film 611s is exposed using the halftone mask HM as a photomask. The halftone mask HM includes the transmissive area TA and the semitransmissive area HTA. In the exposing process, at least the semitransmissive area HTA of the halftone mask HM is disposed to overlap the position to form the second side surface 621b of the film forming area control recess 621. In the developing process, the insulating film 611s is developed.

In the insulating film forming process, the insulating film 611s is formed using the photosensitive material. In the exposing process included in the film forming area control recess, the insulating film 611s is exposed using the halftone mask HM that includes the transmissive area TA and the semitransmissive area HTA. The insulating film 611s is developed in the developing process that is performed afterward. As a result, the film forming area control recess 621 is formed. At least the semitransmissive area HTA of the halftone mask HM used in the exposing process is disposed at the positon to overlap the position to form the second side surface 621b of the film forming area control recess 621. Therefore, the exposed and developed insulating film 611s includes the film forming area control recess 621 that includes the second side surface 621b, the angle of which relative to the normal direction to the plate surface of the array board 611b is smaller in comparison to the first side surface 621a. If the photosensitive material is a positive type, the transmissive area TA of the halftone mask HM is disposed at the position to overlap the position to form the first side surface 621a of the film forming area control recess 621. According to such an arrangement of the transmissive area TA, the film forming area control recess 621 of the exposed and developed insulating film 611s includes the first side surface 621a, the angle of which relative to the normal direction to the plate surface of the array board 611b is smaller in comparison to the second side surface 621b. As described above, in the single exposing process, the film forming area control recess 621 that includes the first side surface 621a and the second side surface 621b, the angles of which relative to the normal direction to the plate surface of the array board 611b are different from each other, is formed. Therefore, time that is required for the production can be reduced.

### Eighth Embodiment

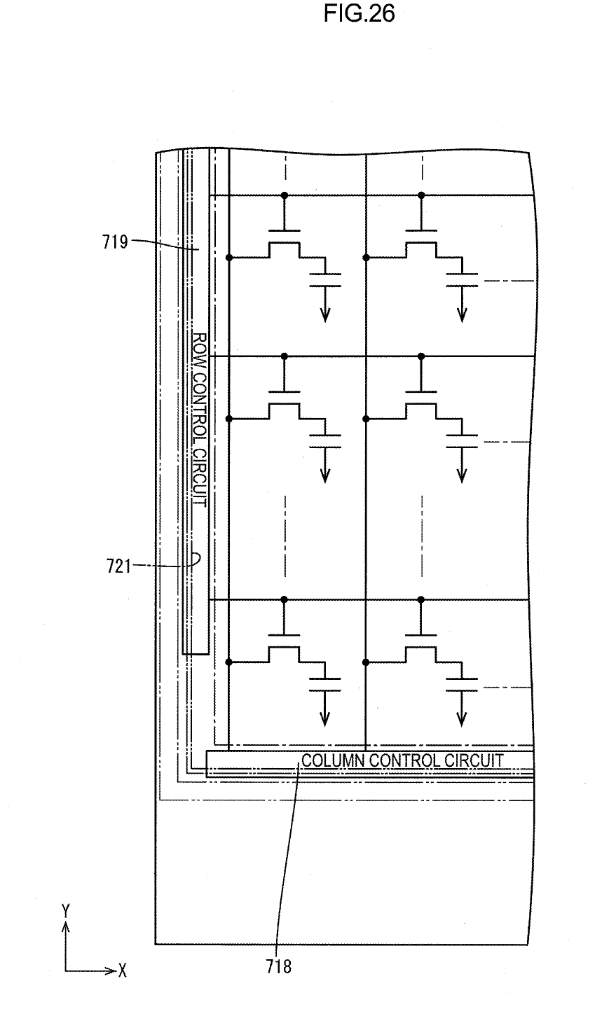

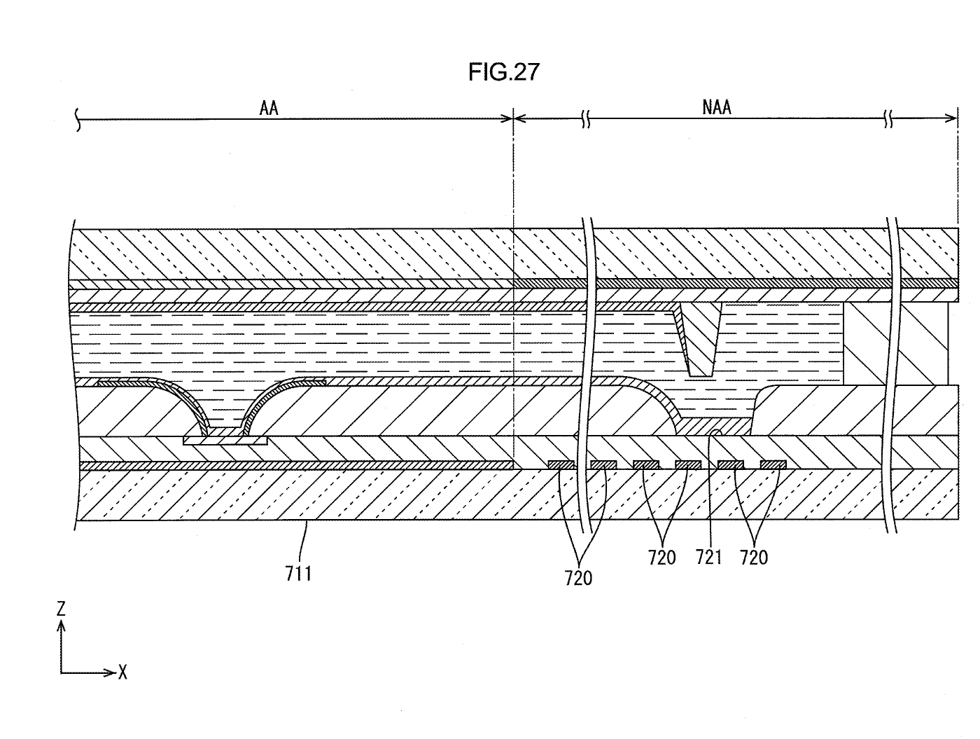

An eighth embodiment will be described with reference to FIGS. 26 and 27. The eighth embodiment includes a film forming area control recess 721 that is disposed differently from the first embodiment. Configurations, functions, and effects similar to those of the first embodiment will not be described.

As illustrated in FIGS. 26 and 27, the film forming area control recess 721 in this embodiment is disposed to overlap traces 720 that are included in control circuits 718 and 719 in a plan view. This configuration is more preferable for reducing the frame size in comparison to the first embodiment.

As described above, the film forming area control recess 721 of a liquid crystal panel 711 in this embodiment is disposed to overlap the traces 720. This configuration is preferable for reducing the frame size.

### Ninth Embodiment

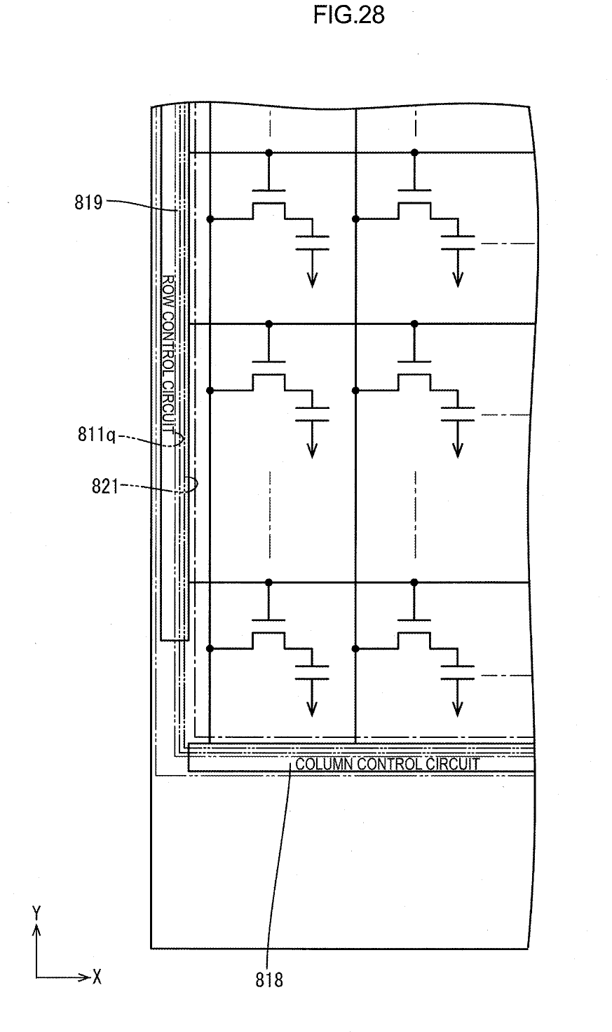

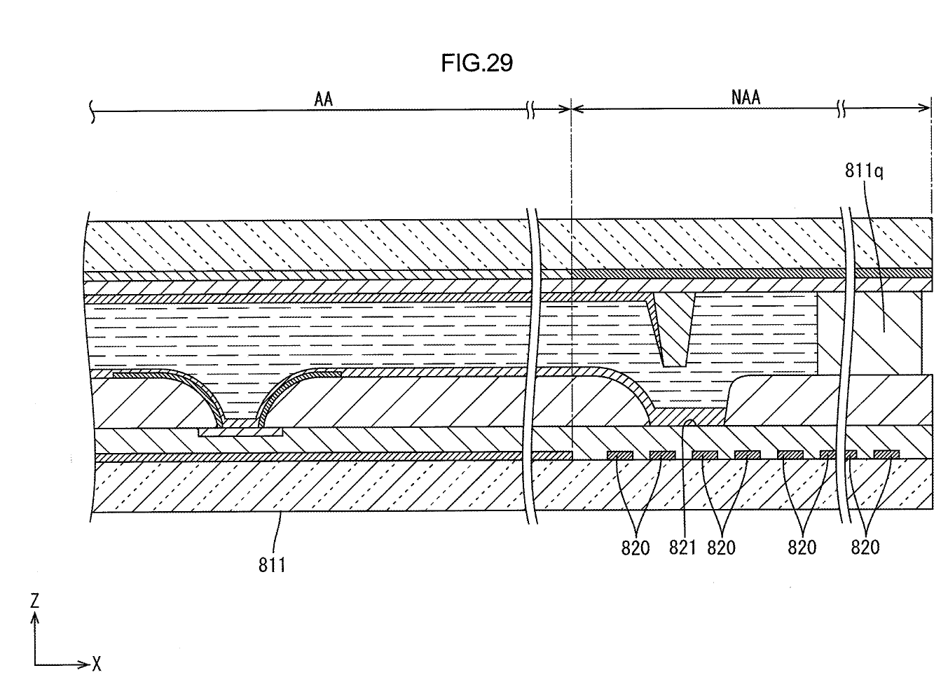

A ninth embodiment will be described with reference to FIGS. 28 and 29. The ninth embodiment includes traces 820 that are disposed differently from the eighth embodiment. Configurations, functions, and effects similar to those of the eighth embodiment will not be described.

As illustrated in FIGS. 28 and 29, the traces 820 that are included in control circuits 818 and 819 in this embodiment are disposed to overlap not only a film forming area control recess 821 but also a sealing member 811q in a plan view. This configuration is further preferable for reducing the frame size in comparison to the eighth embodiment.

As described above, in a liquid crystal panel 811 in this embodiment, the film forming area control recess 821 is disposed to overlap the traces 820 and the sealing member 811q. This configuration is further preferable for reducing the frame size.

### Other Embodiments

The present invention is not limited to the above embodiments described in the above sections and the drawings. For example, the following embodiments may be included in technical scopes of the present invention.

(1) In each of the above embodiments, the resist is formed using the photolithography method in the resist forming process that is included in the film forming area control recess forming process. However, the resist may be formed using a screen printing method in the resist forming process. In this case, a material other than the photosensitive material may be selected for the resist.

(2) In each of the first to the fifth embodiments, the dry etching is performed in the etching process that is included in the film forming area control recess forming process. However, wet etching may be performed in the etching process.

(3) As modifications of the first to the fifth embodiments, a negative type photosensitive material may be used for the insulating film. In such a case, a photomask that includes a light blocking film that includes a hole at apposition corresponding to the non-exposed area of the insulating film be used in the interim film forming area control recess forming process.

(4) In each of the first to the fifth embodiment, the insulating film that is made of the photosensitive material is exposed and then developed using the photomask in the interim film forming area control recess forming process. However, in the interim film forming area control recess forming process, a resist may be formed on the insulating film (a resist forming process), the resist may be etched via the resist (an etching process), and then the resist may be removed from the insulating film (a resist removal process).

(5) As modifications of the sixth and the seventh embodiments, a negative-type photosensitive material may be used for the insulating film. In such a case, the transmissive area of the halftone mask or the gray tone mask may be disposed at a position not to overlap at least the positions to form the first side surface and the second side surface of the film forming area control recess of the insulating film. According to the arrangement, the angle of the first side surface of the exposed and developed insulating film relative to the normal direction to the plate surface of the array board is smaller in comparison to the second side surface.

(6) In each of the above embodiments, the film forming area control recess and the second forming areal control recess or recesses are formed in frame shapes (closed loop shapes) along the display area and the sealing member in the plan view. However, either the film forming area control recess or the second forming area control recess or recesses or both the film forming area control recess and the second forming area control recess or recesses may be linearly formed or formed in dots.

(7) In the first embodiment, the first side surface of the film forming area control recess is the sloped surface having the linear cross section. However, the first side surface may have an arc-shaped cross section.

(8) In each of the above embodiments, the second side surface of the film forming area control recess has the arc-shaped cross section. However, the second side surface may be a sloped surface having a linear cross section.

(9) In each of the second to the fifth embodiments, the gentle slope of the first side surface of the film forming area control recess has the arc-shaped cross section. However, the gentle slope may be a sloped surface having a linear cross section. Alternatively, the steep slope of the first side surface may have an arc-shaped cross section.

(10) In each of the second to the fifth embodiments, the first side surface of the film forming area control recess includes two sections having the different angles, However, the first side surface of the film forming area control recess may include three or more sections having different angles.

(11) In each of the third to the fifth embodiments, the bottom surface of the second film forming area control recess and the boundary between the gentle slope and the steep slope of the first side surface are at the same height. However, the bottom surface of the second film forming area control recess may be at a height different from the height at which the boundary between the gentle slope and the steep slope of the first side surface is disposed.

(12) In each of the fourth and the fifth embodiments, three second film forming area control recesses are provided. However, two second film forming area control recesses or four or more second film forming area control recesses may be provided.

(13) In each of the fourth and the fifth embodiments, the bottom surface of the step and the bottom surface of the second film forming area control recess or the boundary between the gentle slope and the steep slope of the first side surface are at the same height. However, the bottom surface of the step may be disposed at a height different from the height at which the bottom surface of the second film forming area control recess or the boundary between the gentle slope and the steep slope of the first side surface.

(14) In the fifth embodiment, the distal end surface of the board support and the distal end surface of the bank portion are at the same height. However, the distal end surface of the board support and the distal end surface of the bank portion may be disposed at different heights. The arrangement of the board support can be altered as appropriate as long as the film forming area control recess and the second film forming area control recesses do not overlap each other.

(15) The technical features of the sixth embodiment may be combined with any one of the second to the fifth embodiments.

(16) The technical features of the seventh embodiment may be combined with any one of the second to the fifth embodiments.

(17) The technical features of the eighth embodiment may be combined with any one of the second to the seventh embodiments.

(18) The technical features of the ninth embodiment may be combined with any one of the second to the seventh embodiments.

(19) In each of the above embodiments, the polyimide is used as the material of the alignment film However, a liquid crystal alignment material other than the polyimide may be used as a material of the alignment film.

(20) In each of the above embodiment sections, the liquid crystal panel that includes the row control circuit and the column control circuit (the monolithic circuits) and the method of producing the liquid crystal panel are described. However, the present invention can be applied to a liquid crystal panel that includes only one of the row control circuit and the column control circuit or do not include the row control circuit and the column control circuit and to a method of producing the liquid crystal panel.

(21) In each of the above embodiment sections, the liquid crystal panel having the rectangular plan-view shape and the method of producing the liquid crystal panel are described. However, the present invention may be applied to liquid crystal panels having a square plan-view shape, a round plan-view shape, and an oval plan-view shape and methods of producing the liquid crystal panels.

(22) In each of the above embodiments, the driver is COG-mounted on the array board of the liquid crystal panel. However, the driver may be chip-on-film (COF) mounted on the liquid crystal panel flexible circuit board.

(23) In each of the above embodiments, the semiconductor film of the channels of the TFT is made of the oxide semiconductor material. Other than that, continuous grain (OG) silicon, which is one kind of polysilicon or amorphous silicon may be used as a material for the semiconductor film.

(24) In each of the above embodiments, the liquid crystal panel is configured to operate in FFS mode. However, the present invention may be applied to a liquid crystal panel that is configured to operate in other mode such as in-plane switching (IPS) mode and vertical alignment (VA) mode.

(25) In each of the above embodiments, the color filters of the liquid crystal panel have the three-color configuration of red, green, and blue. However, the present invention may be applied to color filters have a four-color configuration including yellow color portions in addition to the red, the green, and the blue color portions.

(26) In each of the above embodiment sections, the liquid crystal panel in the size that is classified into small size or small-to-medium size and the method of producing the liquid crystal panel are described. However, the present invention may be applied to a liquid crystal panel in medium size or large size (or extra-large size) having a screen size of 20 to 100 inches and a method of producing the liquid crystal panel. In such a case, the liquid crystal panel may be used for an electronic device such as a television device, an electronic signboard (a digital signage), and an electrical blackboard.

(27) In each of the above embodiment sections, the liquid crystal panel that includes the liquid crystal layer that is sandwiched between the boards and the method of producing the liquid crystal panel are described. However, the present invention may be applied to a display panel that includes functional organic molecules other than the liquid crystals sandwiched between the boards and a method of producing the display panel.

(28) In each of the above embodiments, the TFTs are used as the switching components of the liquid crystal panel. However, the present invention may be applied to a liquid crystal panel that includes switching components other than TFTs (e.g., thin film diodes (TFD)). The present invention may be applied to a liquid crystal panel that is configured to display black-and-white images other than the liquid crystal panel that is configured to display color images and a method of producing the liquid crystal panel.

### EXPLANATION OF SYMBOLS

11, 111, 211, 311, 411, 711, 811: Liquid crystal panel (Display panel)

11a, 411a: CF board (Second board, Pair of boards)

11b, 111b, 411b, 511b, 611b: Array board (First board, Pair of boards)

11c, 411c: Liquid crystal layer (Internal space)

11o, 111o, 211o, 411o: Alignment film

11q, 111q, 211q, 311q, 811q: Sealing member

11s, 111s, 211s, 311s, 411s, 511s, 611s: Insulating film

20, 220, 720, 820: Trace

21, 121, 221, 321, 421, 521, 621, 721, 821: Film forming area control recess

21IN, 121IN, 221IN, 321IN: Interim film forming area control recess

21a, 121a, 221a, 321s, 521a, 621a: First side surface

21aIN, 121aIN, 221aIN, 321aIN: Interim first side surface

21b, 121b, 521b, 621b: Second side surface

22, 222, 322: Steep slope

23, 223, 323: Gentle slope

24, 324, 424: Second film forming area control recess

24a, 324a, 24a: Bottom surface

25, 425: Step

26: Board support

AA: Display area

GM: Grey tone mask

HM: Halftone mask

HTA: Semitransmissive area

NAA: Non-display area

R1-R3: Resist

Ra1-Ra3: Hole

TA: Transmissive area

1. A display panel comprising:
a pair of boards including sections in a display area and sections in a non-display area outside the display area, the boards being opposed to each other with an internal space therebetween;
a sealing member disposed in the non-display area between the boards to surround the internal space and to seal the internal space;
an insulating film formed on a first board of the boards;
an alignment film disposed in at least the section of the first board in the display area to overlap the insulating film; and
a film forming area control recess formed by recessing a section of the insulating film at a position closer to the display area relative to the sealing member on the first board to control a forming area to form the alignment film, the film forming area control recess including a first side surface on a sealing member side and a second side surface on an opposite side from the sealing member side, at least a section of the first side surface is angled relative to a normal direction to a plate surface of the first board with a smaller angle in comparison to the second side surface.

2. The display panel according to claim 1, wherein the film forming area control recess is disposed in the non-display area.

3. The display panel according to claim 1, wherein the first side surface of the film forming area control recess includes at least a steep slope and a gentle slope, the steep slope being angled relative to the normal direction to the plate surface of the first board with a smaller angle in comparison to the second side surface, the gentle slope being disposed closer to the display area in comparison to the steep slope and angled relative to the normal direction to the plate surface of the first board with a larger angle in comparison to the steep slope.

4. The display panel according to claim 3, further comprising a second film forming area control recess formed by recessing a section of the insulating film on an opposite side from the sealing member side relative to the film forming area control recess, the second film forming area control recess being shallower than the film forming area control recess, wherein
the second film forming area control recess includes a bottom surface that is at a height aligned with a height at which a boundary between the gentle slope and the steep slope of the film forming area control recess.

5. The display panel according to claim 1, further comprising a second film forming area control recess formed by recessing a section of the insulating film on an opposite side from the sealing member side relative to the film forming area control recess.

6. The display panel according to claim 5, wherein
the second film forming area control recess is shallower than the film forming area control recess.

7. The display panel according to claim 5, wherein
the second board of the boards includes a board support protruding toward the first board to support the first board, and
the board support is disposed not to overlap the film forming area control recess and the second film forming area control recess.

8. The display panel according to claim 1, wherein the insulating film includes a step at a position to overlap the sealing member.

9. The display panel according to claim 1, further comprising a trace disposed to overlap the insulating film on an opposite side from an alignment film side on the first board in the non-display area.

10. The display panel according to claim 9, wherein the film forming area control recess is disposed to overlap the trace.

11. The display panel according to claim 9, wherein the film forming area control recess is disposed to overlap the trace and the sealing member.

12. A method of producing a display panel, the method comprising at least:
an insulating film forming process of forming an insulating film on a first board of a pair of boards including sections in a display area and sections in a non-display area outside the display area, the boards being opposed to each other with an internal space therebetween, the internal space being sealed with a sealing member disposed in the non-display area to surround the internal space;
a film forming area control recess forming process of forming a film forming area control recess by recessing at least a section of the insulating film on the first board at a position closer to the display area relative to a position to form the sealing member such that at least a section of a first side surface of the film forming area control recess on a sealing member side is angled relative to a normal direction to a plate surface of the first board with a smaller angle in comparison to a second side surface of the film forming area control recess on an opposite side from the sealing member side, the film forming area control recess being for controlling a forming area to form an alignment film;
an alignment film forming process of forming the alignment film to overlap the insulating film on the first board; and
a sealing member forming process of forming a sealing member between the boards.

13. The method of producing a display panel according to claim 12, wherein
the film forming area control recess forming process comprises at least:
an interim film forming area control recess forming process of temporarily forming an interim film forming area control recess in the sealing member at least at a position closer to the display area relative to a position to form the sealing member, the interim film forming area control recess including an interim first side surface and the second side surface angled relative to a normal direction to a plate surface of the first board with angles equal to each other;
a resist forming process of forming a resist including a hole at least at a position to overlap the interim first side surface of the interim film forming area control recess of the insulating film;
an etching process of etching the insulating film via the resist; and
a resist removal process of removing the resist from the insulating film.

14. The method of producing a display panel according to claim 13, wherein dry etching is performed in the etching process.

15. The method of producing a display panel according to claim 12, wherein
in the insulating film forming process, the insulating film is formed using a photosensitive material, and
the film forming area control recess forming process comprises at least:
an exposing process of exposing the insulating film using a halftone mask or a grey tone mask as a photomask, the halftone mask including a transmissive area and a semitransmissive area, the grey tone mask including a transmissive area and a semitransmissive area, the halftone mask or the grey tone mask being disposed such that at least the semitransmissive area is at a position to overlap a position to form the second side surface; and
a developing process of developing the insulating film.
